(19) United States
(12) Patent Application Publication
(10) Pub. No.: US 2020/0052180 A1
(43) Pub. Date: Feb. 13, 2020

(54) THERMOELECTRIC CONVERSION MODULE

(71) Applicant: FUJIFILM Corporation, Tokyo (JP)

(72) Inventors: Naoyuki HAYASHI, Kanagawa (JP); Hiroki SUGIURA, Kanagawa (JP)

(73) Assignee: FUJIFILM Corporation, Tokyo (JP)

(21) Appl. No.: 16/657,892

(22) Filed: Oct. 18, 2019

Related U.S. Application Data
(63) Continuation of application No. PCT/JP2018/017686, filed on May 8, 2018.

(30) Foreign Application Priority Data
Jun. 28, 2017 (JP) 2017-125991
Oct. 6, 2017 (JP) 2017-195761

(51) Int. Cl. H01L 35/32; H01L 35/34

(52) U.S. Cl. CPC H01L 35/325; H02N 11/002; H01L 35/34

(57) ABSTRACT

A thermoelectric conversion module has a long support, a plurality of first metal layers formed on one surface of the support at intervals in a longitudinal direction of the support, a plurality of thermoelectric conversion layers formed at intervals in the longitudinal direction of the support, and a connection electrode for connecting the thermoelectric conversion layers adjacent in the longitudinal direction of the support, and a second metal layer formed on the other surface of the support, in which the first and the second metal layers have low rigidity portions that have rigidity lower than rigidity of other regions and extend in a width direction of the support, the low rigidity portions of the first and the second metal layers are formed at the same positions in the longitudinal direction, and the support is alternately bent into a mountain fold and a valley fold at the low rigidity portions.

### CROSS-REFERENCE TO RELATED APPLICATIONS

This application is a Continuation of PCT International Application No. PCT/JP2018/17686, filed on May 8, 2018, which claims priority under 35 U.S.C. § 119(a) to Japanese Patent Application No. 2017-125991, filed on Jun. 28, 2017 and Japanese Patent Application No. 2017-195761, filed on Oct. 6, 2017. Each of the above application(s) is hereby expressly incorporated by reference, in its entirety, into the present application.

### BACKGROUND OF THE INVENTION

### 1. Field of the Invention

The present invention relates to a thermoelectric conversion module.

### 2. Description of the Related Art

Thermoelectric conversion materials capable of converting heat energy to electrical energy and vice versa are used in thermoelectric conversion elements such as power generation elements or Peltier elements which generate power using heat.

Thermoelectric conversion elements are capable of directly converting heat energy to electric power and, advantageously, do not require any movable portions. Therefore, thermoelectric conversion modules (power generation devices) obtained by connecting a plurality of thermoelectric conversion elements are capable of easily obtaining electric power without the need of operation costs by being provided in, for example, heat discharging portions of incineration furnaces, various facilities in plants, and the like.

As a thermoelectric conversion element, a so-called π-type thermoelectric conversion element using a thermoelectric conversion material such as Bi—Te has been known.

The π-type thermoelectric conversion element has a configuration in which a pair of electrodes are provided so as to be separated from each other, and an n-type thermoelectric conversion layer formed of an n-type thermoelectric conversion material is provided on one electrode, while a p-type thermoelectric conversion layer formed of a p-type thermoelectric conversion material is provided on the other electrode, such that the thermoelectric conversion materials are similarly arranged to be separated from each other, with upper surfaces of the two thermoelectric conversion layers being connected by the electrodes.

Further, a plurality of thermoelectric conversion elements are arranged such that the n-type thermoelectric conversion layer and the p-type thermoelectric conversion layer are alternately arranged, and the electrodes underneath the thermoelectric conversion layers are connected in series. Thus, a thermoelectric conversion module including a large number of thermoelectric conversion elements is formed.

The problem of the conventional thermoelectric conversion module is that in the case of production of connecting a large number of thermoelectric conversion layers in series, it takes a lot of time and labor. In addition, the influence of thermal strain due to a difference in thermal expansion coefficient and the change in thermal strain are repeatedly generated, so that an interface fatigue phenomenon is also likely to occur.

As a method for solving such a problem, a thermoelectric conversion module using a support having flexibility such as a resin film has been proposed.

The thermoelectric conversion module is a thermoelectric conversion module in which electrodes are formed on the surface of a long support having flexibility and insulating properties such that a p-type thermoelectric conversion layer and an n-type thermoelectric conversion layer long in a width direction of the support are alternately arranged on the surface of the support in a longitudinal direction of the support and further, each thermoelectric conversion layer is connected in series.

These thermoelectric conversion modules are brought into contact with a heat source by, for example, after bending the support or winding the support in a columnar shape, and arranging a heat conduction plate in the upper and lower portions. In addition, a thermoelectric conversion module is formed by forming a film of a thermoelectric conversion material on the support and bending the support while sandwiching the support between heat insulating plates in some cases.

In such a thermoelectric conversion module, a structure in which a large number of thermoelectric conversion layers are connected in series by electrodes can be formed on the surface of a support having flexibility by using, for example, a film forming technique or a film patterning technique.

Therefore, the time and labor for preparing a large number of connection portions in the case where a large number of thermoelectric conversion layers are connected is significantly small compared to the conventional π-type thermoelectric conversion module described above. In addition, since the support has flexibility, even after the thermoelectric conversion layers, the electrodes, and the like are formed, the support itself is deformed and thus it is possible to form a shape with a relatively high degree of freedom.

As a specific example, WO2017/038773A discloses a bellows-like thermoelectric conversion module obtained by forming an n-type thermoelectric conversion layer and a p-type thermoelectric conversion layer to be alternately arranged on the surface of a long support having flexibility, connecting adjacent n-type and p-type thermoelectric conversion layers by connection electrodes, and alternately bending the support in a mountain fold and a valley fold at the positions of the connection electrodes.

### SUMMARY OF THE INVENTION

In the case where a thermoelectric conversion module is bent and formed in a bellows-like shape, when the shape (height) of the thermoelectric conversion module after bending becomes uneven, heat utilization efficiency is lowered in contact with a heat source. Therefore, although it is necessary to reliably bend the thermoelectric conversion module at a predetermined bending position, there is a concern that the production process may be complicated.

In contrast, the thermoelectric conversion module disclosed in WO2017/038773A has a configuration in which low rigidity portions having rigidity lower than that of other regions and extending in the width direction of the support are provided in the connection electrode (metal layer). Since the thermoelectric conversion module can be reliably mountain-folded or valley-folded at the positions of the low rigidity portions by adopting such a configuration, it is possible to form a thermoelectric conversion module with uniform height by bending the thermoelectric conversion module at predetermined positions without making the production process complicated.

Here, according to the studies of the present inventors, it has been found that the bent shape of the thermoelectric conversion module having the configuration described in WO2017/038773A may be changed over time and/or due to heat. It has been found that since the bent shape of the valley fold portion cannot be maintained and extends while the bent shape of the mountain fold portion is maintained at this time, the shape of the entire thermoelectric conversion module formed in a bellows-like shape is curled to a rear surface side on which the thermoelectric conversion layer and the connection electrode are not formed. In the case where the thermoelectric conversion module is curled while the thermoelectric conversion module is brought into contact with a heat source, a part of the thermoelectric conversion module is separated from the heat source and the contact with the heat source cannot be maintained, so that heat utilization efficiency is lowered.

In addition, it has been found that in the case where the shape is changed, there is a concern that the connection electrode and the thermoelectric conversion layer may be peeled off from each other.

Here, an object of the present invention is to provide a thermoelectric conversion module capable of maintaining a bent shape, exhibiting little change in the power generation capacity even with continuous driving, and suppressing peeling between a connection electrode and a thermoelectric conversion layer.

The present inventors have conducted intensive studies to attain the above object. As a result, it has been found that the above object can be attained by providing a thermoelectric conversion module including: a long support having flexibility and insulating properties; a plurality of first metal layers formed on one surface of the support at intervals in a longitudinal direction of the support; a plurality of thermoelectric conversion layers formed on the same surface of the support as the surface provided with the first metal layers at intervals in the longitudinal direction of the support; connection electrodes for connecting thermoelectric conversion layers adjacent in the longitudinal direction of the support on the same surface of the support as the surface provided with the first metal layers; and a second metal layer formed on a surface of the support opposite to the surface on which the first metal layer is formed, in which the first metal layer has a first low rigidity portion having rigidity lower than that of other regions and extending in a width direction of the support, the second metal layer has a second low rigidity portion having rigidity lower than that of other regions and extending in the width direction of the support, the second low rigidity portions of the second metal layer are formed at the same positions as each first low rigidity portion of the plurality of first metal layers in the longitudinal direction of the support, and the support is alternately bent into a mountain fold and a valley fold at the first low rigidity portions of the plurality of first metal layers and the second low rigidity portions of the second metal layer in the longitudinal direction, and thus have completed the present invention.

That is, it has been found that the above problems can be solved by the following configurations.

(1) A thermoelectric conversion module comprising:

a long support having flexibility and insulating properties;

a plurality of first metal layers formed on one surface of the support at intervals in a longitudinal direction of the support;

a plurality of thermoelectric conversion layers formed on the same surface of the support as the surface provided with the first metal layers at intervals in the longitudinal direction of the support;

a connection electrode for connecting the thermoelectric conversion layers adjacent in the longitudinal direction of the support on the same surface of the support as the surface provided with the first metal layers; and

a second metal layer formed on a surface of the support opposite to the surface on which the first metal layer is formed,

in which the first metal layer has a first low rigidity portion having rigidity lower than rigidity of other regions and extending in a width direction of the support,

the second metal layer has a second low rigidity portion having rigidity lower than rigidity of other regions and extending in the width direction of the support,

the second low rigidity portions of the second metal layer are formed at the same positions as each first low rigidity portion of the plurality of first metal layers in the longitudinal direction of the support, and

the support is alternately bent into a mountain fold and a valley fold at the first low rigidity portions of the plurality of first metal layers and the second low rigidity portions of the second metal layer in the longitudinal direction.

(2) The thermoelectric conversion module according to (1), in which the connection electrode also functions as the first metal layer.

(3) The thermoelectric conversion module according to (1) or (2), in which the plurality of first low rigidity portions are formed at fixed intervals in the longitudinal direction of the support.

(4) The thermoelectric conversion module according to any one of (1) to (3), in which a material forming the first metal layer is the same as a material forming the second metal layer.

(5) The thermoelectric conversion module according to any one of (1) to (4), in which a thickness of the first metal layer is the same as a thickness of the second metal layer.

(6) The thermoelectric conversion module according to any one of (1) to (5), in which a plurality of the second metal layers are formed at intervals in the longitudinal direction of the support.

(7) The thermoelectric conversion module according to any one of (1) to (6), in which the plurality of first metal layers having a fixed length are formed at intervals in a longitudinal direction of the support, and a plurality of the second metal layers having a fixed length are formed at intervals in the longitudinal direction of the support.

(8) The thermoelectric conversion module according to any one of (1) to (7), in which a shape and a size of the second metal layer are the same as a shape and a size of the first metal layer.

(9) The thermoelectric conversion module according to any one of (1) to (8), in which the plurality of first metal layers are bonded to the support, and the second metal layer is bonded to the support.

(10) The thermoelectric conversion module according to any one of (1) to (9), further comprising: an auxiliary electrode in contact with the thermoelectric conversion layer and the connection electrode.

(11) The thermoelectric conversion module according to (10), in which a part of the auxiliary electrode covers a part of the support.

(12) The thermoelectric conversion module according to any one of (1) to (11), in which the first low rigidity portion and the second low rigidity portion are at least one of one or more slits parallel to the width direction of the support or broken line portions parallel to the width direction of the support.

(13) The thermoelectric conversion module according to any one of (1) to (12), in which the plurality of thermoelectric conversion layers include a p-type thermoelectric conversion layer and an n-type thermoelectric conversion layer that are alternately formed in the longitudinal direction of the support.

As described below, according to the present invention, it is possible to provide a thermoelectric conversion module capable of maintaining a bent shape, exhibiting little change in the power generation capacity even with continuous driving, and suppressing peeling between a connection electrode and a thermoelectric conversion layer.

### BRIEF DESCRIPTION OF THE DRAWINGS

FIG. 1 is a front view conceptually showing an example of a thermoelectric conversion module according to the present invention.

FIG. 2 is a partially enlarged plan view of a front surface side of the thermoelectric conversion module shown in FIG. 1.

FIG. 3 is a partially enlarged plan view of a rear surface side of the thermoelectric conversion module shown in FIG. 1.

FIG. 4 is a front view conceptually showing another example of the thermoelectric conversion module according to the present invention.

FIG. 5 is a partially enlarged plan view of a rear surface side of the thermoelectric conversion module shown in FIG. 4.

FIG. 6 is a partially enlarged plan view of a front surface side of another example of the thermoelectric conversion module according to the present invention.

FIG. 7 is a partially enlarged plan view of a front surface side of another example of the thermoelectric conversion module according to the present invention.

FIG. 8 is a perspective view schematically showing another example of the thermoelectric conversion module according to the present invention.

FIG. 9 is a conceptual view for explaining an example of a method of producing the thermoelectric conversion module according to the present invention.

FIG. 10 is a conceptual view for explaining the example of the method of producing the thermoelectric conversion module according to the present invention.

FIG. 11 is a conceptual view for explaining the example of the method of producing the thermoelectric conversion module according to the present invention.

FIG. 12 is a conceptual view for explaining the example of the method of producing the thermoelectric conversion module according to the present invention.

FIG. 13 is a conceptual view for explaining the example of the method of producing the thermoelectric conversion module according to the present invention.

FIG. 14 is a conceptual view for explaining the example of the method of producing the thermoelectric conversion module according to the present invention.

FIG. 15 is a conceptual view for explaining the example of the method of producing the thermoelectric conversion module according to the present invention.

FIG. 16 is a conceptual view for explaining the example of the method of producing the thermoelectric conversion module according to the present invention.

FIG. 17 is a conceptual view for explaining the example of the method of producing the thermoelectric conversion module according to the present invention.

FIG. 18 is a conceptual view for explaining the example of the method of producing the thermoelectric conversion module according to the present invention.

### DESCRIPTION OF THE PREFERRED EMBODIMENTS

Hereinafter, a thermoelectric conversion module according to an embodiment of the present invention will be described based on preferable embodiments shown in the accompanying drawings.

The description of configuration requirements described below is made based on a representative embodiment of the present invention but the invention is not limited to the embodiments.

In the present specification, a numerical range represented by using “to” indicates a range including the numerical values before and after “to” as the lower limit and the upper limit.

In the present specification, the expressions “same” and “equivalent” include an error range generally allowable in the technical field. In addition, in the present specification, when the expression “all”, “any” or “entire surface” is used, the expression excludes an error range generally allowable in the technical field in addition to the case of 100%, and also includes for example, the case of 99% or more, 95% or more, or 90% or more.

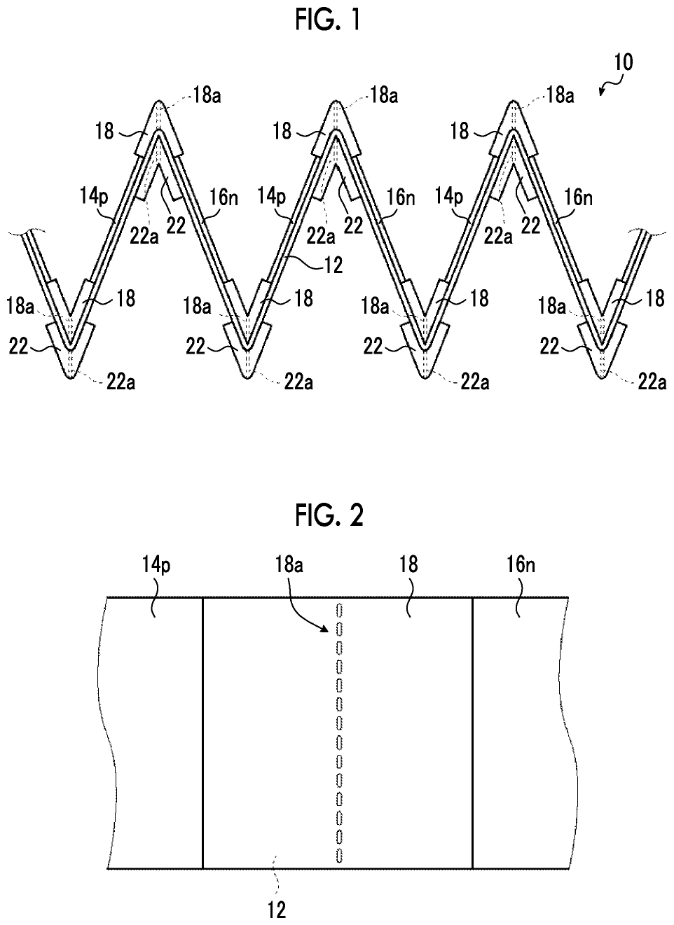

FIG. 1 conceptually shows an example of a thermoelectric conversion module according to an embodiment of the present invention. FIG. 1 is a front view and is a view showing the thermoelectric conversion module according to the embodiment of the present invention as viewed from a plane direction of a support.

As shown in FIG. 1, a thermoelectric conversion module 10 has a support 12, a p-type thermoelectric conversion layer 14p, an n-type thermoelectric conversion layer 16n, a connection electrode 18, and a second metal layer 22.

In the thermoelectric conversion module 10 shown in the example in the drawing, as a preferable embodiment, the connection electrode 18 also functions as a first metal layer in the present invention.

In the present specification, the case where the connection electrode also functions as the first metal layer refers to the case where the connection electrode is the first metal layer and also refers to the case where the first metal layer connects the thermoelectric conversion layers. In this case, the first metal layer and the connection electrode may be respectively provided or only one of the connection electrode and the first metal layer may be provided and the other may not be provided as shown in the example in the drawing.

As shown in FIG. 1, the thermoelectric conversion module 10 has the connection electrodes 18 having a fixed length that are formed on one surface of the long support 12 at fixed intervals in the longitudinal direction of the support 12, and the p-type thermoelectric conversion layers 14p and the n-type thermoelectric conversion layers 16n having a fixed length that are alternately formed on the same surface of the support 12 at fixed intervals in the longitudinal direction of the support 12. In addition, the thermoelectric conversion module 10 has second metal layers 22 having a fixed length at fixed intervals in the longitudinal direction of the support 12 on the other surface of the long support 12, that is, the surface opposite to the surface on which the connection electrode 18 (first metal layer) is formed.

In the present invention, the length in the longitudinal direction and the interval in the longitudinal direction refer to the length and the interval in a state in which the thermoelectric conversion module 10 is spread in a plane shape.

In addition, in the present specification, the surface of the support 12 on which the connection electrode 18 (first metal layer), the p-type thermoelectric conversion layer 14p, and the n-type thermoelectric conversion layer 16n are formed is referred to as a front surface side and the surface on which the second metal layer 22 is formed is referred to as a rear surface side.

In the following description, the term “the longitudinal direction of the support 12” is “longitudinal direction”. As is clear from FIG. 1, the longitudinal direction is a horizontal direction (left and right direction) in FIG. 1. The width direction of the support 12 is a direction orthogonal to the longitudinal direction of the support 12.

In the following description, the “thermoelectric conversion module 10” is also referred to as a “module 10”.

In addition, the module 10 is formed in a bellows-like shape by being alternately bent into a mountain fold and a valley fold along folding lines parallel to the width direction of the support 12 in the connection electrode 18 and the second metal layer 22. Accordingly, the module 10 alternately has a top portion (mountain portion) and a bottom portion (valley portion) in the longitudinal direction by bellows-like folding.

These folding lines, that is, a first low rigidity portion 18a of the connection electrode 18 (first metal layer) and a second low rigidity portion 22a of the second metal layer 22, which will be described later, are formed at fixed intervals in the longitudinal direction.

In the present specification, a bent portion bent convexly as viewed from the front surface (the surface on which the connection electrode 18 is formed) side is referred to as a top portion (mountain portion or mountain fold portion) and a bent portion bent concavely as viewed from the front surface side is referred to as a bottom portion (valley portion or valley fold portion).

The module 10 has a configuration in which the p-type thermoelectric conversion layer 14p and the n-type thermoelectric conversion layer 16n are alternately arranged in the longitudinal direction of the front surface of the support 12, the connection electrode 18 for electrically connecting the p-type thermoelectric conversion layer 14p and the n-type thermoelectric conversion layer 16n is arranged between the p-type thermoelectric conversion layer 14p and the n-type thermoelectric conversion layer 16n. Accordingly, one connection electrode 18 has a configuration in which one end portion of the connection electrode in the longitudinal direction is connected to any one of p-type thermoelectric conversion layer 14p and the n-type thermoelectric conversion layer 16n at in the longitudinal direction and the other end portion is connected to the other thermoelectric conversion layer.

The module 10 generates power by providing a high temperature heat source on the rear surface (the lower side in FIG. 1) and a low temperature heat source (such as heat dissipation means such as a heat dissipation fin) on the front surface (on the upper side in FIG. 1) and causing a temperature difference between the front surface and the rear surface (the up and down direction in FIG. 1). In other words, power is generated by causing a temperature difference in the in-plane direction (conducting direction) of the thermoelectric conversion layers sandwiched between the connection electrodes 18.

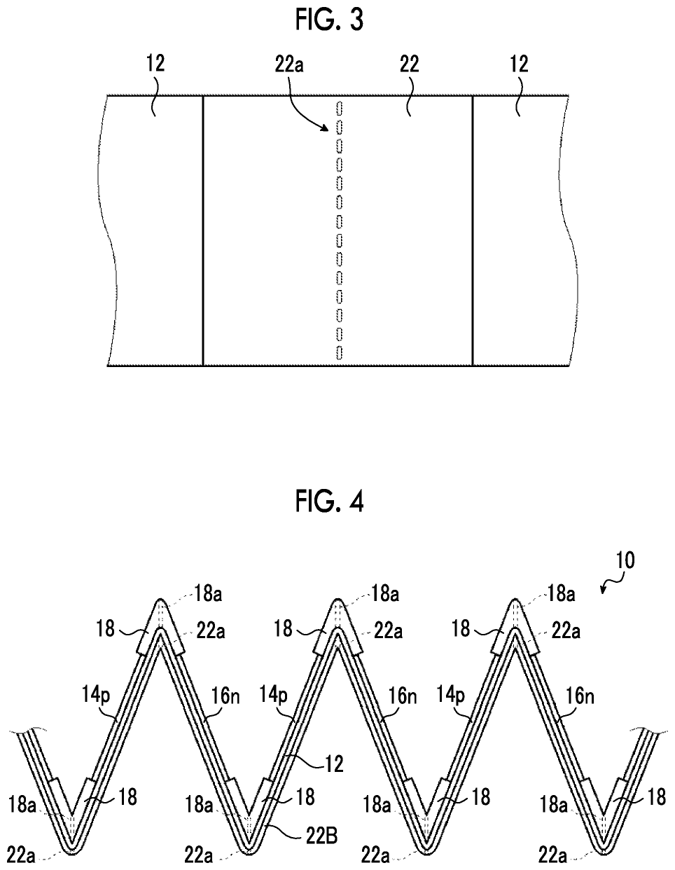

Here, as shown in FIG. 2, in the module 10 according to the embodiment of the present invention, the connection electrode 18 formed on the front surface side of the support 12 has a first low rigidity portion 18a having rigidity lower than that of other regions of the connection electrode 18 parallel to the width direction of the support 12. In addition, as shown in FIG. 3, the second metal layer 22 formed on the rear surface side of the support has a second low rigidity portion 22a having rigidity lower than that of other regions of the second metal layer 22 parallel to the width direction of the support 12. In addition, the first low rigidity portion 18a of the connection electrode 18 and the second low rigidity portion 22a of the second metal layer 22 are formed at the same position in the longitudinal direction of the support 12.

The module 10 according to the embodiment of the present invention is bent in a bellows-like shape as shown in FIG. 1 by being alternately bent into a mountain fold and a valley fold at the positions of the first low rigidity portions 18a and the second low rigidity portions 22a formed at the same positions.

As described above, by adopting the configuration in which the low rigidity portion having rigidity lower than that of other regions and extending in the width direction of the support is provided in the connection electrode, the module can be reliably mountain-folded or valley-folded at the position of the low rigidity portion. However, it is found that there is a concern that the shape bent over time may be changed and/or due to heat only with such a configuration.

According to the studies of the present inventors, in the case of the configuration in which a metal layer (connection electrode) having a low rigidity portion is provided only on the front surface side of the support, at the top portion of the mountain fold, force is applied to the metal layer in the extension direction and force is applied to the support in the contraction direction. On the other hand, at the bottom portion of the valley fold, force is applied to the metal layer in the contraction direction and force is applied to the support in the extension direction. Since the support has flexibility and insulating properties, the support is basically formed using a resin. Accordingly, since the plastic deformation properties differ between the support and the metal layer, the bent shape is easily maintained at the top portion of the mountain fold in the direction in which the metal layer extends, but the bent shape is not easily maintained at the bottom portion of the valley fold in the direction in which the support extends. Therefore, it is found that the bent shape of the bottom portion cannot be maintained over time and/or due to heat and the shape of the entire thermoelectric conversion module formed in a bellows-like shape is curled to the rear surface side on which the thermoelectric conversion layer and the connection electrode are not formed.

In contrast, the thermoelectric conversion module 10 according to the embodiment of the present invention has a configuration in which the first metal layer 18 having the first low rigidity portion 18a is provided on the front surface side of the support 12, the second metal layer 22 having the second low rigidity portion 22a is provided on the rear surface side of the support 12, the first low rigidity portion 18a and the second low rigidity portion 22a are formed at the same position in the longitudinal direction, and the module is alternately bent into a mountain fold and a valley fold in the first low rigidity portion 18a and the second low rigidity portion 22a.

By adopting such a configuration, at the top portion of the mountain fold, force is applied to the first metal layer (connection electrode 18) in the extension direction and force is applied to the second metal layer 22 in the contraction direction. On the other hand, at the bottom portion of the valley fold, force is applied to the first metal layer (connection electrode 18) in the contraction direction and force is applied to the second metal layer 22 in the extension direction. Since both the first metal layer and the second metal layer 22 are formed of a metal and are easily plastically deformed, the bent shape can be maintained at the top portion and the bottom portion. Therefore, the bent state of the top portion and the bottom portion can be maintained over time and/or in the case where heat is applied, and the shape of the entire thermoelectric conversion module formed in a bellows-like shape can be maintained. Thus, since the thermoelectric conversion module can be prevented from being separated from a heat source even with continuous driving, and contact with the heat source can be maintained, it is possible to prevent a decrease in heat utilization efficiency and to reduce the change in the power generation capacity.

Since the change of the shape is small, it is possible to suppress peeling between the connection electrode and the thermoelectric conversion layer.

The module 10 is bent by bending the connection electrode 18 in the longitudinal direction. By providing the first low rigidity portion 18a and the second low rigidity portion 22a having rigidity lower than that of other regions parallel to the width direction (hereinafter, in the case where there is no need to distinguish the low rigidity portions, collectively referred to as a low rigidity portion), the connection electrode 18 can be selectively bent at the position of the low rigidity portion. Thus, it is possible to reliably confirm a predetermined bending position without making the production process complicated.

Here, the first low rigidity portion 18a and the second low rigidity portion 22a are preferably formed at equal intervals in the longitudinal direction. Thus, in all the connection electrodes 18, the position of the top portion of the mountain fold portion and the position of the bottom portion of the valley fold portion can be aligned.

As described above, the module 10 according to the embodiment of the present invention generates heat by causing a temperature difference in the up and down direction in FIG. 1, that is, between the mountain fold portion (top portion or mountain portion) and the valley fold portion (bottom portion or valley portion) folded in a bellows-like shape. Accordingly, the connection electrodes 18 on the high temperature side and the low temperature side can be efficiently brought into contact with the high temperature heat source and the low temperature heat source by aligning the positions of all the top portions of the mountain fold portions and the bottom portions of the valley fold portions, and heat utilization efficiency is improved, so that efficient power generation can be performed.

Further, although described later, in the production of the module 10 according to the embodiment of the present invention, all the formation of the connection electrode 18 having the first low rigidity portion 18a, the formation of the second metal layer 22 having the second low rigidity portion 22a, the formation of the thermoelectric conversion layer, bending processing, and the like can be performed using a so-called roll-to-roll process. Accordingly, the module 10 is a thermoelectric conversion module that can be produced with high productivity and good handleability.

The interval between the first low rigidity portion 18a and the second low rigidity portion 22a in the longitudinal direction may be appropriately set according to the height required for the module 10 folded in a bellows-like shape and the like. In contrast, in the case where the height of the module 10 is limited, the interval between the first low rigidity portion 18a and the second low rigidity portion 22a in the longitudinal direction may be set according to the limitation of the height, and the size of the connection electrode 18, the second metal layer 22, the p-type thermoelectric conversion layer 14p, and the n-type thermoelectric conversion layer 16n in the longitudinal direction may be set according to the interval between the first low rigidity portion 18a and the second low rigidity portion 22a.

The height of the module 10 is the size of the module 10 in the up and down direction in FIG. 1, that is, the size of the module 10 in the direction in which the high temperature heat source and the low temperature heat source are arranged.

In the module 10 according to the embodiment of the present invention, the first low rigidity portion 18a and the second low rigidity portion 22a are not limited to the broken line portions as shown in the example in the drawing, and in the case where the planar connection electrode 18 and second metal layer 22 having low rigidity compared to other regions are bent in the longitudinal direction, various configurations can be used as long as the portions are selectively bent in the connection electrode 18 and in the second metal layer 22.

As an example, a low rigidity portion that is formed by arranging one slit or a plurality of slits long in the width direction in the width direction, a low rigidity portion that is formed by forming a thin portion, which is thinner than other regions, in the shape of a groove parallel to the width direction, and the like may be mentioned.

A low rigidity portion such as a configuration in which a broken line portion is provided in the vicinity of the end portion in the width direction and a slit is provided at the center portion in the width direction may be formed using a plurality of rigidity reduction methods in combination.

Here, it is required to form a low rigidity portion in a region which becomes the low rigidity portion so that the metal layer (connection electrode (first metal layer) or second metal layer) is present. That is, in the case where the metal layer is viewed from the longitudinal direction, it is required to form a low rigidity portion so that at least a part in the width direction has a region in which the metal layer is present over the entire region in the longitudinal direction.

In the case where a region without a metal layer is formed so as to penetrate the support in the width direction, after the support 12 is bent, the support 12 may return to the original plane shape by the elasticity and rigidity of the support 12.

In contrast, by setting a state in which the metal layer remains in the low rigidity portion such as the broken line portion as shown in the example in the drawing, after the support 12 is bent, a state in which the support 12 is bent can be maintained by the plastic deformation of the metal layer. In addition, in the case where the first metal layer also functions as the connection electrode 18 as in the module 10 in the example in the drawing, the thermoelectric conversion layers can be electrically connected.

Regarding the amount of the remaining metal layer in the low rigidity portion, the amount in which the state in which the support 12 is bent can be maintained by the plastic deformation of the metal layer may be appropriately set according to the thickness and the rigidity of the metal layer and the like.

In addition, in order to make the bent top portion and bottom portion uniform, the kind of the material of the first metal layer (connection electrode 18) and the kind of the material of the second metal layer 22 are preferably the same.

Similarly, the thickness of the first metal layer (connection electrode 18) and the thickness of the second metal layer 22 are preferably the same.

Similarly, the planar shape and size of the first metal layer (connection electrode 18) and the planar shape and size of the second metal layer 22 are preferably the same.

In addition, in order to make the bent top portion and bottom portion uniform, the shape of the first low rigidity portion 18a and the shape of the second low rigidity portion 22a are preferably the same.

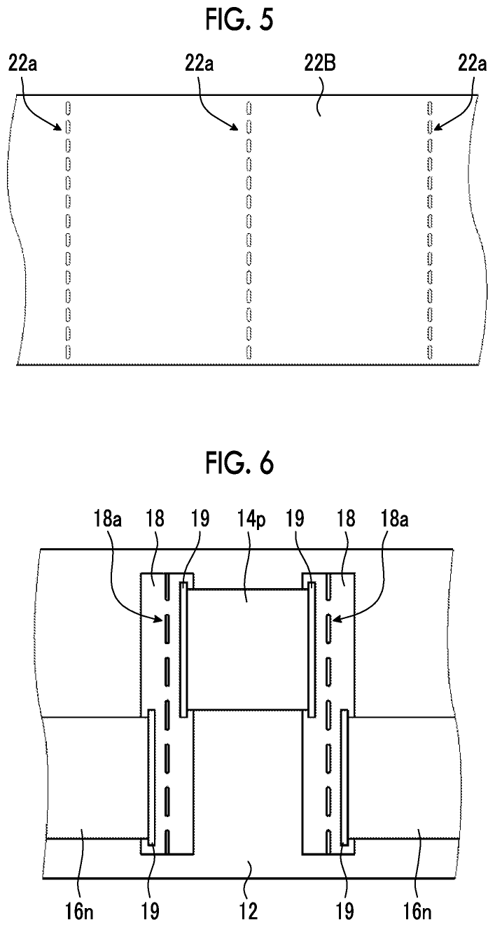

Here, in the example shown in FIG. 1, the plurality of the second metal layers 22 are formed at intervals in the longitudinal direction and each second metal layer 22 has one second low rigidity portion 22a. However, the present invention is not limited to this configuration. As shown in FIG. 4, the second metal layer 22B may be formed over the entire surface of the rear surface side of the support 12 and as shown in FIG. 5, the plurality of the second low rigidity portions 22a may be formed in the second metal layer 22B formed over the entire surface at predetermined intervals in the longitudinal direction.

In addition, in the example shown in FIG. 1, the p-type thermoelectric conversion layer 14p and the n-type thermoelectric conversion layer 16n are formed over the entire surface of the support 12 in the width direction is adopted. However, the present invention is not limited to this configuration. As shown in the example in FIG. 6, the width of the p-type thermoelectric conversion layer 14p and the n-type thermoelectric conversion layer 16n may be set to a half or less of the width of the support 12, and the position of the p-type thermoelectric conversion layer 14p and the position of the n-type thermoelectric conversion layer 16n in the width direction may be shifted from each other so as not to overlap each other. By adopting such configurations, it is possible to prevent the contact between the p-type thermoelectric conversion layer 14p and the n-type thermoelectric conversion layer 16n at bending.

The thermoelectric conversion module according to the embodiment of the present invention preferably has an auxiliary electrode in contact with the thermoelectric conversion layer (p-type thermoelectric conversion layer 14p or n-type thermoelectric conversion layer 16n) and the connection electrode 18.

In the example shown in FIG. 6, an auxiliary electrode 19 in contact with thermoelectric conversion layer (p-type thermoelectric conversion layer 14p or n-type thermoelectric conversion layer 16n) and the connection electrode 18 is provided at each of the connection position of the p-type thermoelectric conversion layer 14p and the connection electrode 18 and the connection position of the n-type thermoelectric conversion layer 16n and the connection electrode 18. In the example shown in FIG. 6, the end portion of the thermoelectric conversion layer is formed on the front surface of the connection electrode 18, and the auxiliary electrode 19 is formed so as to cover the end portion of the thermoelectric conversion layer and a part of the front surface of the connection electrode 18. By providing such an auxiliary electrode, the electrical connection between the thermoelectric conversion layer and the connection electrode 18 can be made more reliable. In addition, the peeling of the thermoelectric conversion layer and the connection electrode 18 can be suppressed.

The size and shape of the auxiliary electrode 19 may be appropriately set according to the size of the module 10, the width of the support 12, the size of the p-type thermoelectric conversion layer 14p and the n-type thermoelectric conversion layer 16n, the distance between the electrodes, and the like.

In the example shown in FIG. 6, the auxiliary electrode 19 has a rectangular shape in which the length in the width direction is the length that is long enough to cover the end side of the thermoelectric conversion layer in the longitudinal direction and the length in the longitudinal direction is shorter than the length of the connection electrode 18. In the example shown in FIG. 6, the auxiliary electrode 19 is in contact only with the thermoelectric conversion layer and the connection electrode 18.

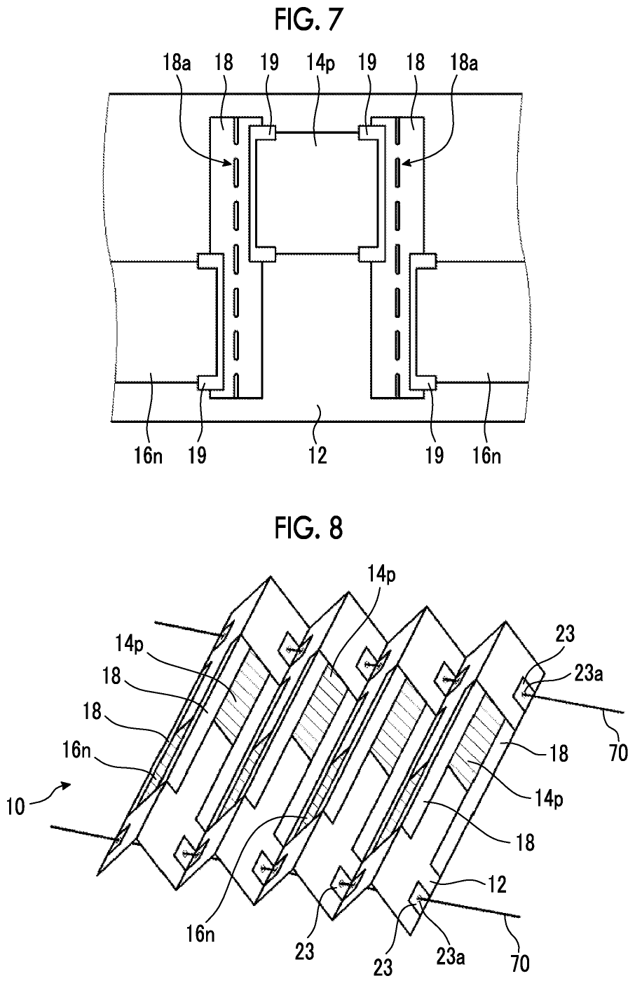

In addition, a part of the auxiliary electrode 19 may cover a part of the support. For example, as shown in FIG. 7, the auxiliary electrode 19 may have a substantially C shape, and the auxiliary electrode may cover the end side of the thermoelectric conversion layer in the longitudinal direction and may cover a part of the end side of the thermoelectric conversion layer in the width direction. In the example shown in FIG. 7, the auxiliary electrode 19 is in contact with the thermoelectric conversion layer, the connection electrode 18, and the support 12.

As the material of the auxiliary electrode 19, the same conductive material as the material of the connection electrode 18 can be used.

As shown in the example in FIG. 8, a through-hole 23a may be formed for each fold in both end portions of the support 12 bent in a bellows-like shape in the width direction, and two wires 70 inserted into the plurality of through-holes 23a may be provided.

In the example shown in FIG. 8, the p-type thermoelectric conversion layer 14p, the n-type thermoelectric conversion layer 16n, and the connection electrode 18 are arranged at the center portion of the support 12 in the width direction. On each of both end portion sides of the support 12 on which these components are not arranged, the plurality of through-holes 23a are formed. The plurality of through-holes 23a are formed for each fold and the through-holes are formed at positions that overlap each other in a state in which the bellows is closed.

In addition, a reinforcing member 23 for preventing the strength of the support 12 from being lowered due to the formation of the through-hole is arranged in the vicinity of the formation position of the through-hole 23a.

By allowing the wire 70 to be inserted into the bellows-like module 10, both end portions of the wire 70 can be connected and fixed, and the shape of the bellows-like module 10 can be held in a shape formed along the curved shape of the surface of the heat source.

Hereinafter, each portion of the thermoelectric conversion module 10 according to the embodiment of the present invention will be described in detail.

The support 12 is long and has flexibility and insulating properties.

In the module 10 according to the embodiment of the present invention, various long sheet-like materials (films) used in known thermoelectric conversion modules using a flexible support can be used for the support 12 as long as the material has flexibility and insulating properties.

Specific examples thereof include sheet-like materials formed of polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalenedicarboxylate, resins such as polyimide, polycarbonate, polypropylene, polyethersulfone, cycloolefin polymer, polyether ether ketone (PEEK), and triacetyl cellulose (TAC), glass epoxy, and liquid crystal polyester.

Among these, from the viewpoint of thermal conductivity, heat resistance, solvent resistance, ease of availability, and economy, sheet-like materials formed of polyimide, polyethylene terephthalate, polyethylene naphthalate, and the like are suitably used.

Regarding the thickness of the support 12, a thickness which provides sufficient flexibility and functions as the support 12 may be appropriately set according to the material for forming the support 12, and the like.

According to the studies of the present inventors, the thickness of the support 12 is preferably 25 μm or less, more preferably 15 μm or less, and still more preferably 13 μm or less.

The module 10 of the present invention is required to be able to maintain a state in which the module is alternately bent into a mountain fold and a valley fold. In the module 10, the bending is maintained by the plastic deformation of the connection electrode 18, that is, the first metal layer, and the second metal layer 22. Here, in a case where the support 12 is thick, the connection electrode 18 and the second metal layer 22 may not be able to maintain the bending of the support 12. In contrast, by setting the thickness of the support 12 to 25 μm or less and preferably 15 μm or less, the bending of module 10 can be more suitably maintained by the connection electrode 18 and the second metal layer 22.

It is preferable that the thickness of the support 12 is 25 μm or less and preferably 15 μm or less from the viewpoint of being capable of improving the heat utilization efficiency.

The length and width of the support 12 may be appropriately set according to the size and use of the module 10 or the like.

On one surface of the support 12, the p-type thermoelectric conversion layers 14p and the n-type thermoelectric conversion layers 16n having a fixed length are alternately provided at fixed intervals in the longitudinal direction.

The module 10 of the embodiment of the present invention is not limited to the configuration having both the p-type thermoelectric conversion layer 14p and the n-type thermoelectric conversion layer 16n. That is, in the module of the embodiment of the present invention, only the p-type thermoelectric conversion layers 14p may be arranged at intervals in the longitudinal direction or only the n-type thermoelectric conversion layers 16n may be arranged at intervals in the longitudinal direction.

From the viewpoint of power generation efficiency or the like, as shown in the example in the drawing, it is preferable that the module has both the p-type thermoelectric conversion layer 14p and the n-type thermoelectric conversion layer 16n.

In the following description, in the case where there is no need to distinguish the p-type thermoelectric conversion layer 14p and the n-type thermoelectric conversion layer 16n, both thermoelectric conversion layers are also collectively referred to as “thermoelectric conversion layer”.

In the module 10 according to the embodiment of the present invention, for the p-type thermoelectric conversion layer 14p and the n-type thermoelectric conversion layer 16n, various thermoelectric conversion layers formed of known thermoelectric conversion materials can be used.

As the thermoelectric conversion material constituting the p-type thermoelectric conversion layer 14p and the n-type thermoelectric conversion layer 16n, for example, nickel or a nickel alloy may be used.

As the nickel alloy, various nickel alloys that generate power by causing a temperature difference can be used. Specific examples thereof include nickel alloys mixed with one or two or more of vanadium, chromium, silicon, aluminum, titanium, molybdenum, manganese, zinc, tin, copper, cobalt, iron, magnesium, and zirconium.

In the case where nickel or a nickel alloy is used for the p-type thermoelectric conversion layer 14p and/or the n-type thermoelectric conversion layer 16n, the nickel content in the p-type thermoelectric conversion layer 14p and the n-type thermoelectric conversion layer 16n is preferably 90% by atom or more and the nickel content is more preferably 95% by atom or more, and the p-type thermoelectric conversion layer 14p and the n-type thermoelectric conversion layer 16n are particularly preferably formed of nickel. The p-type thermoelectric conversion layer 14p and the n-type thermoelectric conversion layer 16n formed of nickel include inevitable impurities.

In the case where a nickel alloy is used as the thermoelectric conversion material for the p-type thermoelectric conversion layer 14p, chromel having nickel and chromium as main components is typically used. In the case where a nickel alloy is used as the thermoelectric conversion material for the n-type thermoelectric conversion layer 16n, constantan having copper and nickel as main components is typically used.

In addition, in the case where nickel or a nickel alloy is used for the p-type thermoelectric conversion layer 14p and/or the n-type thermoelectric conversion layer 16n and also nickel or a nickel alloy is used for the connection electrode 18, the p-type thermoelectric conversion layer 14p, the n-type thermoelectric conversion layer 16n, the connection electrode 18 may be integrally formed.

As other thermoelectric conversion materials that can be used for the p-type thermoelectric conversion layer 14p and the n-type thermoelectric conversion layer 16n, in addition to nickel and nickel alloys, for example, the following materials may be used. Incidentally, the components in parentheses indicate the material composition.

Examples of the materials include BiTe-based materials (BiTe, SbTe, BiSe and compounds thereof), PbTe-based materials (PbTe, SnTe, AgSbTe, GeTe and compounds thereof), Si—Ge-based materials (Si, Ge, SiGe), silicide-based materials (FeSi, MnSi, CrSi), skutterudite-based materials (compounds represented by MX₃ or RM₄X₁₂, where M equals Co, Rh, or Ir, X equals As, P, or Sb, and R equals La, Yb, or Ce), transition metal oxides (NaCoO, CaCoO, ZnInO, SrTiO, BiSrCoO, PbSrCoO, CaBiCoO, BaBiCoO), zinc antimony-based compounds (ZnSb), boron compounds (CeB, BaB, SrB, CaB, MgB, VB, NiB, CuB, LiB), cluster solids (B cluster, Si cluster, C cluster, AlRe, AlReSi), and zinc oxides (ZnO).

In addition, for the thermoelectric conversion material used for the p-type thermoelectric conversion layer 14p and/or the n-type thermoelectric conversion layer 16n, materials that can be made into paste can be used so that a film can be formed by coating or printing.

Specific examples of such thermoelectric conversion materials include organic thermoelectric conversion materials such as a conductive polymer and a conductive nanocarbon material.

Examples of the conductive polymer include a polymer compound having a conjugated molecular structure (conjugated polymer). Specific examples thereof include known π-conjugated polymers such as polyaniline, polyphenylene vinylene, polypyrrole, polythiophene, polyfluorene, acetylene, and polyphenylene. Particularly, polydioxythiophene can be suitably used.

Specific examples of the conductive nanocarbon material include carbon nanotubes, carbon nanofiber, graphite, graphene, and carbon nanoparticles. These may be used singly or in combination of two or more thereof. Among these, from the viewpoint of further improving thermoelectric properties, carbon nanotubes are preferably used. In the following description, the term “carbon nanotubes” is also referred to as CNTs.

CNT is categorized into single layer CNT of one carbon film (graphene sheet) wound in the form of a cylinder, double layer CNT of two graphene sheets wound in the form of concentric circles, and multilayer CNT of a plurality of graphene sheets wound in the form of concentric circles. In the present invention, each of the single layer CNT, the double layer CNT, and the multilayer CNT may be used singly, or two or more thereof may be used in combination. Particularly, the single layer CNT and the double layer CNT excellent in conductivity and semiconductor characteristics are preferably used, and the single layer CNT is more preferably used.

The single layer CNT may be semiconductive or metallic. Furthermore, semiconductive CNT and metallic CNT may be used in combination. In the case where both of the semiconductive CNT and the metallic CNT are used, a content ratio between the CNTs can be appropriately adjusted. In addition, CNT may contain a metal or the like, and CNT containing fullerene molecules and the like may be used.

An average length of CNT is not particularly limited and can be appropriately selected. Specifically, from the viewpoint of ease of manufacturing, film formability, conductivity, and the like, the average length of CNT is preferably 0.01 to 2,000 μm, more preferably 0.1 to 1,000 μm, and particularly preferably 1 to 1,000 μm, though the average length also depends on an inter-electrode distance.

A diameter of CNT is not particularly limited. From the viewpoint of durability, transparency, film formability, conductivity, and the like, the diameter is preferably 0.4 to 100 nm, more preferably 50 nm or less, and particularly preferably 15 nm or less. Particularly, in the case where the single layer CNT is used, the diameter of CNT is preferably 0.5 to 2.2 nm, more preferably 1.0 to 2.2 nm, and particularly preferably 1.5 to 2.0 nm.

The CNT contains defective CNT in some cases. Because the defectiveness of the CNT deteriorates the conductivity of the thermoelectric conversion layer, it is preferable to reduce the amount of the defective CNT. The amount of defectiveness of the CNT can be estimated by a G/D ratio between a G band and a D band in a Raman spectrum. In the case where the G/D ratio is high, a material can be assumed to be a CNT material with a small amount of defectiveness. The G/D ratio is preferably 10 or higher and more preferably 30 or higher.

In the present invention, modified or treated CNT can also be used. Examples of the modification and treatment methods include a method of incorporating a ferrocene derivative or nitrogen-substituted fullerene (azafullerene) into CNT, a method of doping CNT with an alkali metal (potassium or the like) or a metallic element (indium or the like) by an ion doping method, and a method of heating CNT in a vacuum.

In the case where CNT is used for the p-type thermoelectric conversion layer 14p and/or the n-type thermoelectric conversion layer 16n, in addition to the single layer CNT or the multilayer CNT, nanocarbons such as carbon nanohorns, carbon nanocoils, carbon nanobeads, graphite, graphene, amorphous carbon, and the like may be contained in the composition.

In the case where CNT is used for the p-type thermoelectric conversion layer 14p and/or the n-type thermoelectric conversion layer 16n, it is preferable that the thermoelectric conversion layers include a p-type dopant or an n-type dopant.

(p-Type Dopant) Examples of the p-type dopant include halogen (iodine, bromine, or the like), Lewis acid (PF₅, AsF₅, or the like), protonic acid (hydrochloric acid, sulfuric acid, or the like), transition metal halide (FeCl₃, SnCl₄, or the like), a metal oxide (molybdenum oxide, vanadium oxide, or the like), and an organic electron-accepting material. Examples of the organic electron-accepting material suitably include a tetracyanoquinodimethane (TCNQ) derivative such as 2,3,5,6-tetrafluoro-7,7,8,8-tetracyanoquinodimethane, 2,5-dimethyl-7,7,8,8-tetracyanoquinodimethane, 2-fluoro-7,7,8,8-tetracyanoquinodimethane, or 2,5-difluoro-7,7,8,8-tetracyanoquinodimethane, a benzoquinone derivative such as 2,3-dichloro-5,6-dicyano-p-benzoquinone or tetrafluoro-1,4-benzoquinone, 5,8H-5,8-bis(dicyanomethylene)quinoxaline, dipyrazino[2,3-f:2′,3′-h]quinoxaline-2,3,6,7,10,11-hexacarbonitrile, and the like.

In addition, strong acid salts of amines (such as ammonium chloride and trimethyl ammonium chloride), and strong acid salts of heterocyclic compounds containing a nitrogen atom (such as pyridine hydrochloride or imidazole hydrochloride) shown below as the p-type dopant can be suitably used.

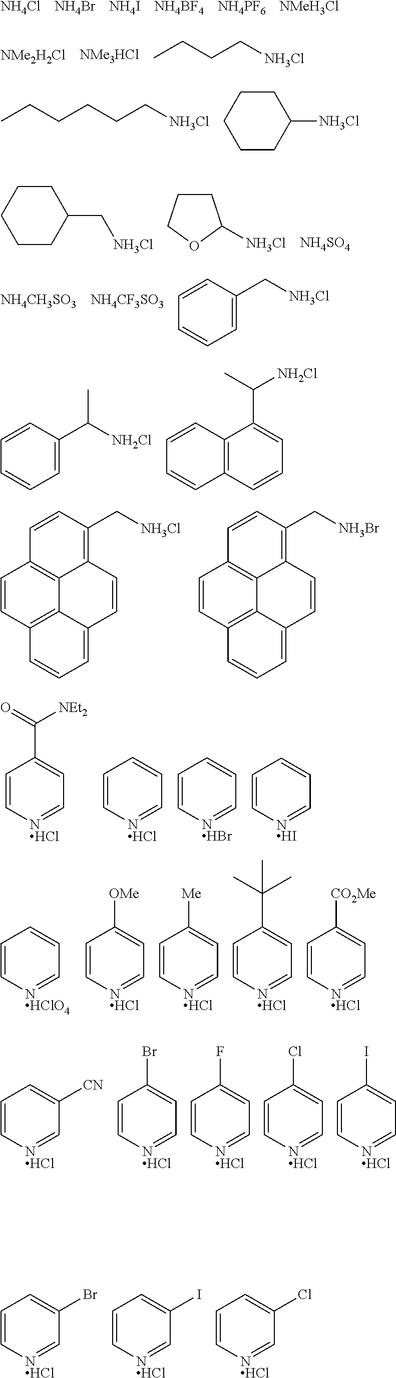

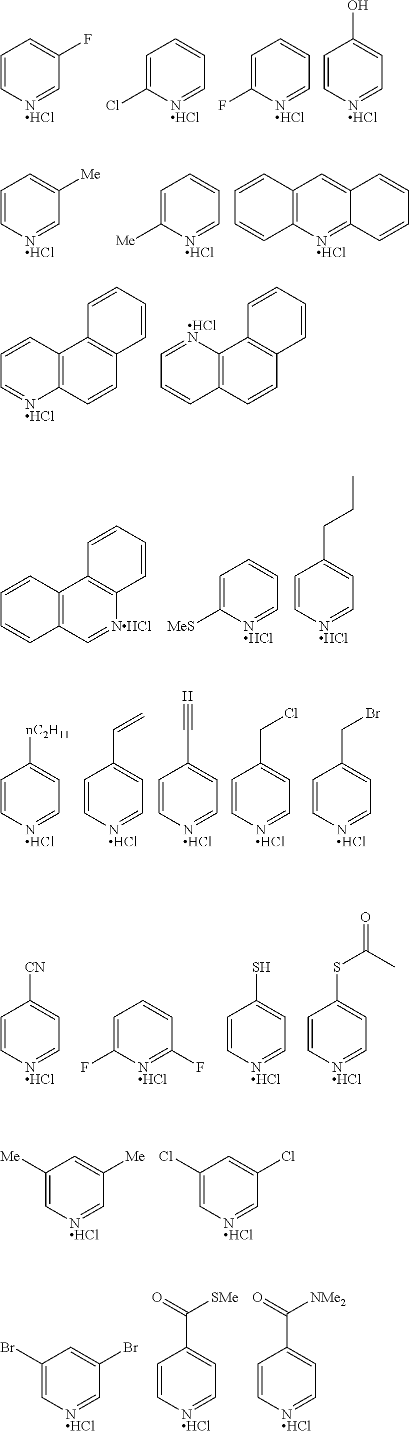

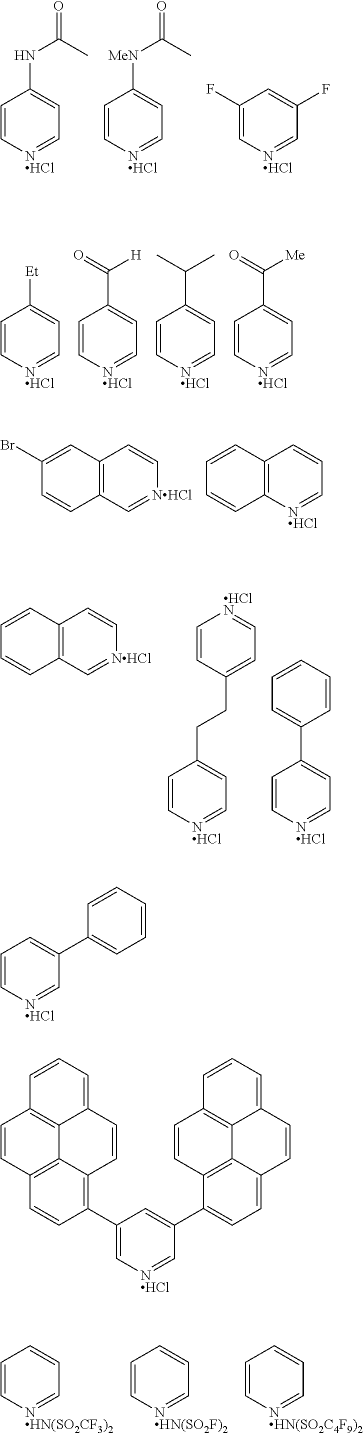

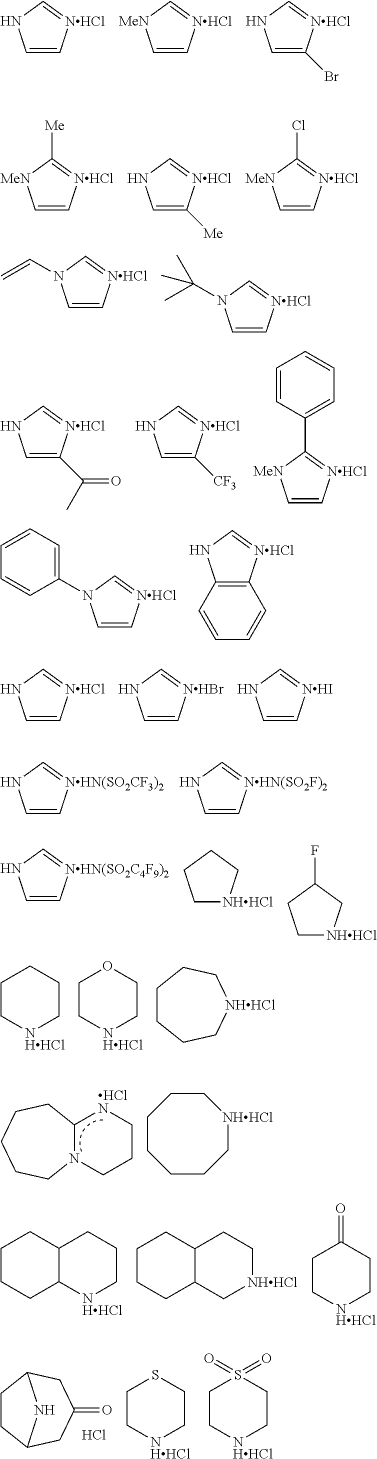

Among these p-type dopants, from the viewpoint of the stability of the materials, the compatibility with CNT, and the like, organic electron-accepting materials such as strong acid salts of amines, strong acid salts of heterocyclic compounds containing a nitrogen atom, tetracyanoquinodimethane (TCNQ) derivatives or benzoquinone derivatives are suitably exemplified.

The p-type dopants may be used singly or in combination of two or more thereof.

(n-Type Dopant)

As the n-type dopant, known materials such as (1) alkali metals such as sodium and potassium, (2) phosphines such as triphenylphosphine and ethylenebis(diphenylphosphine), (3) polymers such as polyvinyl pyrrolidone and polyethylene imine, and the like can be used.

Examples thereof include polyalkylene glycol type higher alcohol ethylene oxide adducts, alkylene oxide adducts of phenol, naphthol or the like, fatty acid alkylene oxide adducts, polyhydric alcohol fatty acid ester alkylene oxide adducts, higher alkylamine alkylene oxide adducts, fatty acid amide alkylene oxide adducts, alkylene oxide adducts of fat, polypropylene glycol alkylene oxide adducts, dimethylsiloxane-alkylene oxide block copolymers, and dimethylsiloxane-(propylene oxide-ethylene oxide) block copolymers. In addition, acetylene glycol-based and acetylene alcohol-based oxyalkylene adducts can also be used in the same manner.

In addition, as the n-type dopant, ammonium salts shown below can be suitably used.

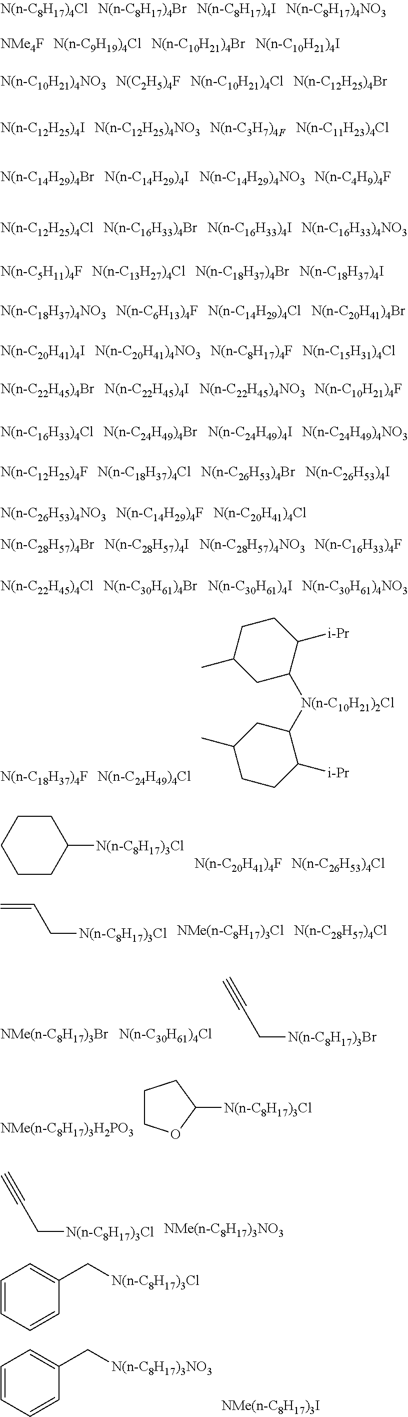

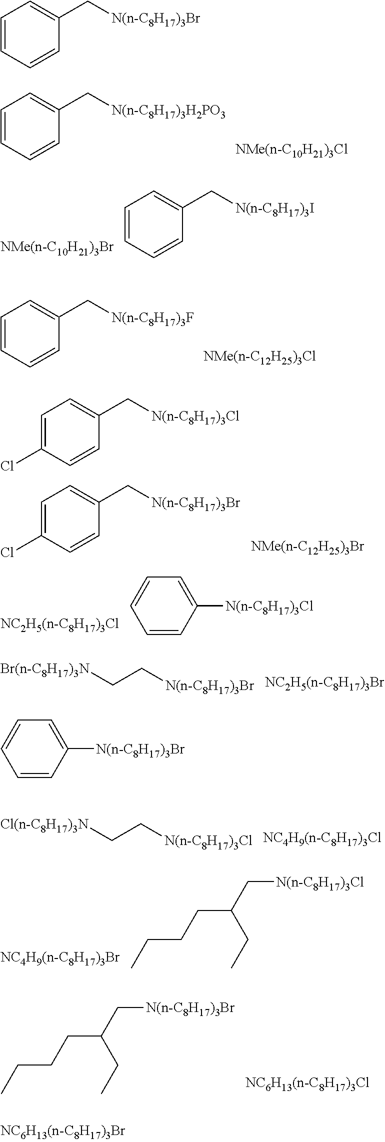

Among the n-type dopants, from the viewpoint of maintaining stable n-type properties in the atmosphere or the like, the above polyalkylene oxide-based compounds and ammonium salts are preferably exemplified.

The n-type dopants may be used singly or in combination of two or more thereof.

As the p-type thermoelectric conversion layer 14p and the n-type thermoelectric conversion layer 16n, thermoelectric conversion layers obtained by dispersing the thermoelectric conversion materials in a resin material (binder) are suitably used.

Among these, the thermoelectric conversion layers obtained by dispersing a conductive nanocarbon material in a resin material are more suitably exemplified. Especially, the thermoelectric conversion layer obtained by dispersing CNT in a resin material is particularly suitably exemplified because this makes it possible to obtain high conductivity and the like.

As the resin material, various known nonconductive resin materials (polymer materials) can be used.

Specifically, a vinyl compound, a (meth)acrylate compound, a carbonate compound, an ester compound, an epoxy compound, a siloxane compound, gelatin, and the like may be used.

More specifically, examples of the vinyl compound include polystyrene, polyvinyl naphthalene, polyvinyl acetate, polyvinyl phenol, and polyvinyl butyral. Examples of the (meth)acrylate compound include polymethyl (meth)acrylate, polyethyl (meth)acrylate, polyphenoxy(poly)ethylene glycol (meth)acrylate, and polybenzyl (meth)acrylate. Examples of the carbonate compound include bisphenol Z-type polycarbonate, and bisphenol C-type polycarbonate. Examples of the ester compound include amorphous polyester.

Polystyrene, polyvinyl butyral, a (meth)acrylate compound, a carbonate compound, and an ester compound are preferable, and polyvinyl butyral, polyphenoxy(poly)ethylene glycol (meth)acrylate, polybenzyl (meth)acrylate, and amorphous polyester are more preferable.

In the thermoelectric conversion layer obtained by dispersing a thermoelectric conversion material in a resin material, a quantitative ratio between the resin material and the thermoelectric conversion material may be appropriately set according to the material used, the thermoelectric conversion efficiency required, the viscosity or solid content concentration of a solution exerting an influence on printing, and the like.

In addition, in the case where CNT is used for the p-type thermoelectric conversion layer 14p and/or the n-type thermoelectric conversion layer 16n, a thermoelectric conversion layer including CNT and a surfactant is also suitably used.

By forming the thermoelectric conversion layer using CNT and a surfactant, the thermoelectric conversion layer can be formed using a coating composition to which a surfactant is added. Therefore, the thermoelectric conversion layer can be formed using a coating composition in which CNT is smoothly dispersed. As a result, by a thermoelectric conversion layer including a large amount of long and less defective CNT, excellent thermoelectric conversion performance is obtained.

As the surfactant, known surfactants can be used as long as the surfactants function to disperse CNT. More specifically, various surfactants can be used as the surfactant as long as surfactants dissolve in water, a polar solvent, or a mixture of water and a polar solvent and have a group adsorbing CNT.

Accordingly, the surfactant may be ionic or nonionic. Furthermore, the ionic surfactant may be any of cationic, anionic, and amphoteric surfactants.

Examples of the anionic surfactant include an aromatic sulfonic acid-based surfactant such as alkylbenzene sulfonate like dodecylbenzene sulfonate or dodecylphenylether sulfonate, a monosoap-based anionic surfactant, an ether sulfate-based surfactant, a phosphate-based surfactant and a carboxylic acid-based surfactant such as sodium deoxycholate or sodium cholate, and a water-soluble polymer such as carboxymethyl cellulose and a salt thereof (sodium salt, ammonium salt, or the like), a polystyrene sulfonate ammonium salt, or a polystyrene sulfonate sodium salt.

Examples of the cationic surfactant include an alkylamine salt and a quaternary ammonium salt. Examples of the amphoteric surfactant include an alkyl betaine-based surfactant, and an amine oxide-based surfactant.

Further, examples of the nonionic surfactant include a sugar ester-based surfactant such as sorbitan fatty acid ester, a fatty acid ester-based surfactant such as polyoxyethylene resin acid ester, and an ether-based surfactant such as polyoxyethylene alkyl ether.

Among these, an ionic surfactant is preferably used, and cholate or deoxycholate is particularly suitably used.

In the thermoelectric conversion layer including CNT and the surfactant, a mass ratio of surfactant/CNT is preferably 5 or less, and more preferably 3 or less.

It is preferable that the mass ratio of surfactant/CNT is 5 or less from the viewpoint that a higher thermoelectric conversion performance or the like is obtained.

If necessary, the thermoelectric conversion layer formed of an organic thermoelectric conversion material may contain an inorganic material such as SiO₂, TiO₂, Al₂O₃, or ZrO₂.

In the case where the thermoelectric conversion layer contains an inorganic material, a content of the inorganic material is preferably 20% by mass or less, and more preferably 10% by mass or less.

The p-type thermoelectric conversion layer 14p and the n-type thermoelectric conversion layer 16n may be formed by a known method. For example, the following method may be used.

First, a coating composition for forming a thermoelectric conversion layer containing a thermoelectric conversion material and required components such as a surfactant is prepared.

Next, the prepared coating composition for forming a thermoelectric conversion layer is applied according to a thermoelectric conversion layer to be formed while being patterned. The application of the coating composition may be performed by a known method such as a method using a mask or a printing method.

After the coating composition is applied, the coating composition is dried by a method according to the resin material, thereby forming the thermoelectric conversion layer. If necessary, after the coating composition is dried, the coating composition (resin material) may be cured by being irradiated with ultraviolet rays or the like.

In addition, the prepared coating composition for forming the thermoelectric conversion layer is applied to the entire surface of the insulating substrate and dried, and then the thermoelectric conversion layer may be formed as a pattern by etching or the like.

In the case where a thermoelectric conversion layer including CNT and a surfactant is formed, it is preferable to form the thermoelectric conversion layer by forming the thermoelectric conversion layer with the coating composition, then immersing the thermoelectric conversion layer in a solvent for dissolving the surfactant or washing the thermoelectric conversion layer with a solvent for dissolving the surfactant and drying the thermoelectric conversion layer.

Thus, it is possible to form the thermoelectric conversion layer having a very small mass ratio of surfactant/CNT by removing the surfactant from the thermoelectric conversion layer and more preferably not containing the surfactant.

The thermoelectric conversion layer is preferably formed as a pattern by printing.

As the printing method, various known printing methods such as screen printing, metal mask printing, and ink jetting can be used. In the case where the thermoelectric conversion layer is formed as a pattern by using a coating composition containing CNT, it is more preferable to use metal mask printing.

The printing conditions may be appropriately set according to the physical properties (solid content concentration, viscosity, and viscoelastic properties) of the coating composition used, the opening size of a printing plate, the number of openings, the opening shape, a printing area, and the like.

In the case where the p-type thermoelectric conversion layer 14p and the n-type thermoelectric conversion layer 16n are formed by using the above-described nickel or a nickel alloy, inorganic materials such as BiTe-based material, other than the formation methods using such coating compositions, a film forming method such as a sputtering method, a vapor deposition method, a chemical vapor deposition (CVD) method, a plating method, or an aerosol deposition method may be used to form the thermoelectric conversion layers.

Alternatively, the thermoelectric conversion layer can be separately formed and bonded to the connection electrode 18 for preparation. For example, buckypaper that is a film-like CNT may be cut according to the arrangement interval between the connection electrodes 18 and bonded to the connection electrodes 18 for preparation.

The size of the p-type thermoelectric conversion layer 14p and the n-type thermoelectric conversion layer 16n may be appropriately set according to the size of the module 10, the width of the support 12, the size of the connection electrode 18, and the like. In the present invention, the size of each configuration means a size of the support 12 in a plane direction.

As described above, the p-type thermoelectric conversion layer 14p and the n-type thermoelectric conversion layer 16n have the same length in the longitudinal direction. In addition, since the thermoelectric conversion layers are formed at fixed intervals, the p-type thermoelectric conversion layers 14p and the n-type thermoelectric conversion layers 16n are alternately formed at equal intervals.

The thickness of the p-type thermoelectric conversion layer 14p and the n-type thermoelectric conversion layer 16n may be appropriately set according to the material for forming the thermoelectric conversion layers, and the like and is preferably 1 to 50 μm, more preferably 1 to 20 μm and particularly preferably 3 to 15 μm.

It is preferable to set the thickness of the p-type thermoelectric conversion layer 14p and the n-type thermoelectric conversion layer 16n to be in the above range from the viewpoint of obtaining good electric conductivity and good printability, and the like.

The thickness of the p-type thermoelectric conversion layer 14p and the thickness of the n-type thermoelectric conversion layer 16n may be the same or different from each other but are preferably about the same.

In addition, it is preferable that the thickness of the p-type thermoelectric conversion layer 14p and the n-type thermoelectric conversion layer 16n is thinner than the connection electrode 18 also functioning as the first metal layer. In the case where the first metal layer and the connection electrode are separately provided, it is preferable that the thickness of the p-type thermoelectric conversion layer 14p and the n-type thermoelectric conversion layer 16n is thinner than the first metal layer.

By adopting such a configuration, in the case where the bellows-like module 10 is compressed in the longitudinal direction as described later, the contact between the p-type thermoelectric conversion layer 14p and the n-type thermoelectric conversion layer 16n cannot be easily made.

In the module 10, the connection electrode 18 is formed on the surface of the support 12 on which the p-type thermoelectric conversion layer 14p and the n-type thermoelectric conversion layer 16n are formed.

The connection electrode 18 is provided for electrically connecting the p-type thermoelectric conversion layer 14p and the n-type thermoelectric conversion layer 16n, which are alternately formed in the longitudinal direction, in series. As described above, in the example shown in FIG. 1, the thermoelectric conversion layers having a fixed length are formed at fixed intervals in the longitudinal direction. Accordingly, the connection electrodes 18 having a fixed length are formed at fixed intervals.

In the module 10 according to the embodiment of the present invention, as long as the intervals between the first low rigidity portions 18a formed in the connection electrodes 18 (first metal layers) described later are constant in the longitudinal direction, the p-type thermoelectric conversion layer 14p, the n-type thermoelectric conversion layer 16n, and the connection electrode 18 do not necessarily have a constant length and interval in the longitudinal direction. In the case where the connection electrode and the first metal layer are separately formed, the length and interval of the first metal layer in the longitudinal direction are the same.

In the module 10, the thermoelectric conversion layers and the connection electrodes 18 may have different lengths, formation intervals, and the like.

As the material for forming the connection electrode 18, as long as the material has a required conductivity, various conductive materials can be used for electrode formation.

Specific examples thereof include metal materials such as copper, silver, gold, platinum, nickel, aluminum, constantan, chromium, indium, iron, and copper alloy, and materials used for transparent electrodes in various devices, such as indium tin oxide (ITO) and zinc oxide (ZnO). Among these, copper, gold, silver, platinum, nickel, copper alloy, aluminum, constantan, and the like are preferably used, copper, gold, silver, platinum, and nickel are more preferably used, and copper and silver are most preferable. Known copper materials include ACP-100 and ACP-2100AX (both manufactured by Asahi Chemical Research Laboratory Co., Ltd.), and known silver materials include FA-333, FA-353N, FA-451A, and FA-705BN (all manufactured by FUJIKURA KASEI CO., LTD.).

In addition, the connection electrode 18 may be a laminated electrode having a configuration in which a copper layer is formed on a chromium layer or the like.

In the case where the connection electrode and the first metal layer are separately formed, as the material forming the first metal layer, all known metal materials including stainless steel can be used and the above-described metal materials may be suitably exemplified.

As described above, in the module 10 shown in FIG. 1, the connection electrode 18 also functions as the first metal layer. Therefore, the first low rigidity portion 18a parallel to the width direction is formed in the connection electrode 18.

The first low rigidity portion 18a is formed at a fixed interval in the longitudinal direction.

The first low rigidity portion 18a is a portion having rigidity lower than that of other portions in the connection electrode 18, that is, a portion that is more easily bent than other portions.

FIG. 2 conceptually shows a plan view showing the module 10 in a partially enlarged manner. The plan view of FIG. 2 is a view as the module 10 is viewed from a direction orthogonal to the front surface (maximum surface) of the support 12, and is a view as the module 10 is viewed from the upper side in FIG. 1.

In the module 10 shown in FIG. 1, by forming the broken line portion parallel to the width direction by the connection electrode 18, the first low rigidity portion 18a parallel to the width direction is formed. In other words, a portion with an electrode (metal) and a portion without an electrode are alternately formed in the width direction in the connection electrode 18 to form the first low rigidity portion 18a.

The size of the connection electrode 18 may be appropriately set according to the size of the module 10, the width of the support 12, the size of the p-type thermoelectric conversion layer 14p and the n-type thermoelectric conversion layer 16n, and the like.

Regarding the thickness of the connection electrode 18, a thickness at which the conductivity of the p-type thermoelectric conversion layer 14p and the n-type thermoelectric conversion layer 16n can be sufficiently secured may be appropriately set according to the forming material.

Here, in the module 10 in which the connection electrode 18 also functions as the first metal layer, the thickness of the connection electrode 18 is preferably 3 μm or more and more preferably 6 μm or more. Further, the thickness of the connection electrode 18 is preferably thinner than the thickness of the support 12.

In the case where the thickness of the connection electrode 18 satisfies the above condition, sufficient conductivity can be secured as an electrode, and the state in which the module 10 is bent in a bellows-like shape can be suitably maintained by the plastic deformation of the connection electrode 18.

From the viewpoint that the configuration of the module 10 shown in the example of the drawing is simple and the production thereof is easily performed, the connection electrode 18 also functions as the first metal layer having a low rigidity portion. In other words, in the module 10 shown in the example of the drawing, the first metal layer having a low rigidity portion also functions as the connection electrode.

However, the present invention is not limited thereto and the connection electrode and the first metal layer may be separately formed. For example, the first metal layer having a low rigidity portion is formed between adjacent p-type thermoelectric conversion layer 14p and n-type thermoelectric conversion layer 16n by electrically separating the p-type thermoelectric conversion layer 14p and the n-type thermoelectric conversion layer 16n from each other, and a connection electrode that is electrically separated from the first metal layer and connects the p-type thermoelectric conversion layer 14p and the n-type thermoelectric conversion layer 16n may be provided on the outer side of the first metal layer in the width direction such as the vicinity of the end portion in the width direction.

In this case, the thickness of the first metal layer may be set according to the thickness of the connection electrode 18 which also functions as the above-described first metal layer. In addition, the thickness of the connection electrode may be appropriately set according to the material forming the connection electrode, the size in the plane direction, and the like so that sufficient conductivity can be obtained.

In the module 10, the second metal layer 22 is formed on the rear surface of the support 12.

The second metal layer 22 may be arranged at the position where the second low rigidity portion 22a can be formed at the same position as the position of the first low rigidity portion 18a formed in the connection electrode 18 (first metal layer) in the longitudinal direction of the support 12. As described above, in the example shown in FIG. 1, the second metal layers 22 having the same length as the connection electrode 18 are arranged at the same arrangement interval.

In the module 10 according to the embodiment of the present invention, as long as the interval of the second low rigidity portion 22a is constant in the longitudinal direction, the length and the interval of the second metal layer 22 in the longitudinal direction are not necessarily constant. As described above, the second metal layer 22 may be formed over the entire rear surface of the support 12.

In addition, in the module 10, the second metal layers 22 may have different lengths, formation intervals, and the like.

As the material forming the second metal layer 22, all known metal materials can be used, and the above-described metal materials used for the connection electrode 18 may be suitably exemplified. In addition, the second metal layer 22 is preferably formed using the same kind of material as the connection electrode 18 (first metal layer).

As described above, the second low rigidity portions 22a are formed in the second metal layers 22 at fixed intervals in the longitudinal direction.

The second low rigidity portion 22a is a portion having rigidity lower than that of other portions in the second metal layer 22, that is, a portion that is more easily bent than the other portions.

FIG. 3 conceptually shows a plan view showing the module 10 in a partially enlarged manner. The plan view of FIG. 3 is a view as the module 10 is viewed from a direction orthogonal to the rear surface (maximum surface) of the support 12, and is a view as the module 10 is viewed from the lower side in FIG. 1.

In the module 10 shown in FIG. 1, by forming the broken line portion parallel to the width direction by the second metal layer 22, the second low rigidity portion 22a parallel to the width direction is formed. In other words, by alternately forming a portion with a metal and a portion without a metal in the second metal layer 22 in the width direction, the second low rigidity portion 22a is formed.

The size of the second metal layer 22 may be appropriately set according to the size of the module 10, the width of the support 12, the size of the p-type thermoelectric conversion layer 14p and the n-type thermoelectric conversion layer 16n, the size of the connection electrode 18, the size of the first metal layer, and the like.

The thickness of the second metal layer 22 is preferably 3 μm or more and more preferably 6 μm or more. Further, the thickness of the second metal layer 22 is preferably thicker than the thickness of the support 12.

In the case where the thickness of the second metal layer 22 satisfies the above condition, the state in which the module 10 is bent in a bellows-like shape can be suitably maintained by the plastic deformation of the second metal layer 22.

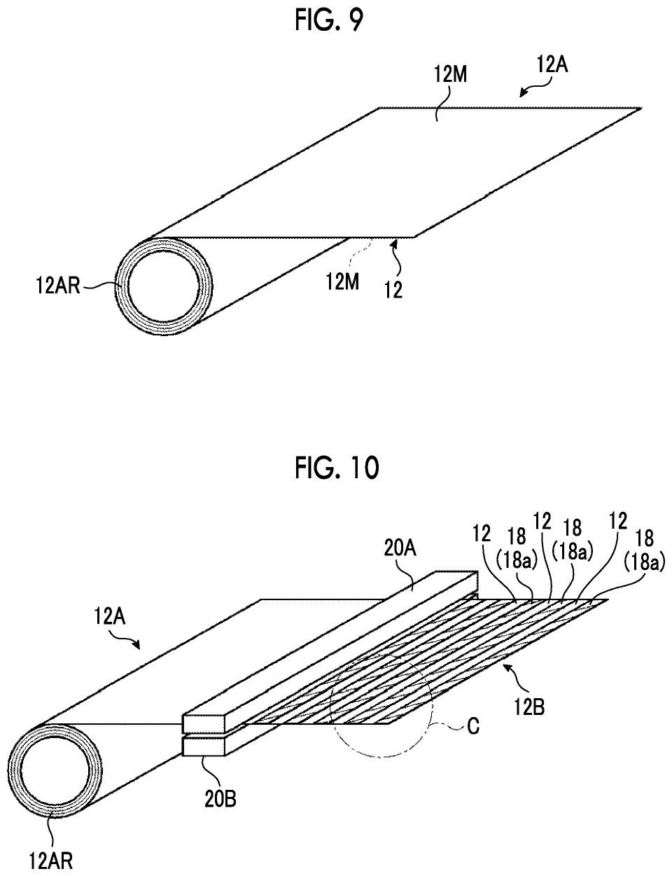

Hereinafter, an example of a method of producing the module 10 according to the embodiment of the present invention will be described with reference to the conceptual views of FIGS. 9 to 17.

A thermoelectric conversion module having a configuration in which a connection electrode and a first metal layer are separate can be basically produced in the same manner.

The following production method is a method using a so-called roll-to-roll process. In the following description, the “roll-to-roll” is also referred to as “R to R”.

As is well known, R to R is a method in which while a long object to be treated is pulled out from a roll formed by winding the object to be treated and the object to be treated is transported in the longitudinal direction, a treated object is wound in a roll shape by performing various treatments such as film formation and surface treatment.

The module 10 according to the embodiment of the present invention can be produced by such R to R. That is, the module 10 has good productivity and further, in the case where the support 12 is a thin film having a thickness of 25 μm or less and preferably 15 μm or less is used, the handleability of an intermediate structure in the step during production is good.

In the production method described below, various operations such as feeding out the support 12 from the roll, transporting the support 12, winding up the treated support 12, and the like may be performed by known methods adopting a device for performing R to R.

First, as shown in FIG. 9, a roll 12AR formed by winding up a laminate 12A in which a metal film 12M such as copper foil is formed over the entire front surface and the entire rear surface of the support 12 is prepared.

Next, as shown in FIG. 10, while the laminate 12A is pulled out from the roll 12AR and transported in the longitudinal direction, the metal film 12M is etched by etching devices 20A and 20B. By etching the metal film 12M, an unnecessary metal film 12M is removed, the connection electrodes 18 having a fixed length are formed on the front surface of the support at fixed intervals in the longitudinal direction, and the first low rigidity portions 18a parallel to the width direction are formed in the connection electrodes 18 at fixed intervals in the longitudinal direction. At the same time, the second metal layers 22 having a fixed length are formed on the rear surface of the support at fixed intervals in the longitudinal direction and the second low rigidity portions 22a parallel to the width direction are formed in the second metal layers 22 at fixed intervals in the longitudinal direction.

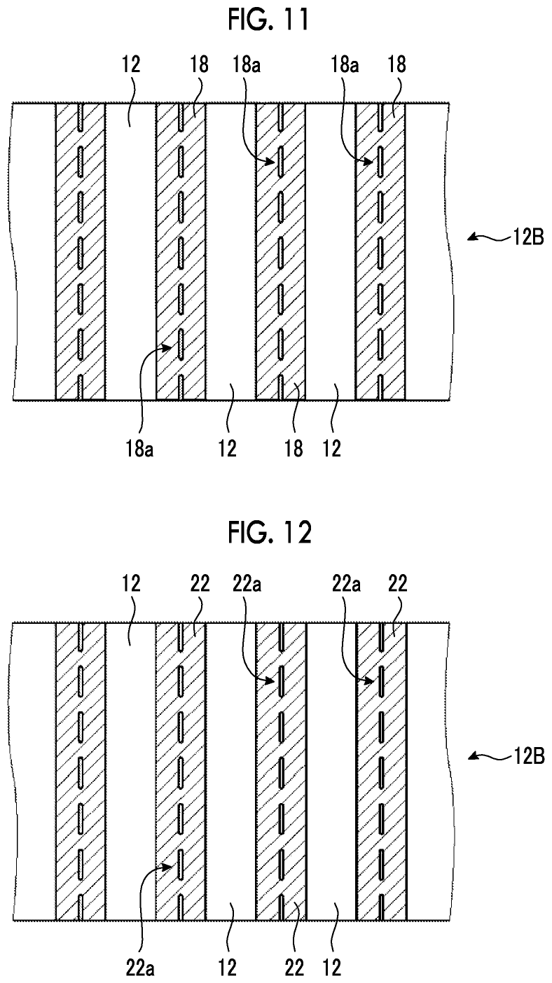

FIG. 11 is a plan view of the front surface of a region C in FIG. 10. FIG. 12 shows a plan view of the rear surface of the region C in FIG. 10. In FIGS. 10 to 14, the connection electrode 18 and the second metal layer 22 are hatched for easy understanding of the configuration.

Although not shown in FIGS. 9 and 10, a support 12B on which the connection electrode 18, the first low rigidity portion 18a, the second metal layer 22, and the second low rigidity portion 22a are formed is wound in a roll shape to form a support roll 12BR.

The formation of the connection electrode 18, the first low rigidity portion 18a, the second metal layer 22, and the second low rigidity portion 22a by etching of the metal film 12M may be performed by a known method. Examples thereof include a method of removing the metal film 12M by laser beam ablation and a method of performing etching by photolithography.

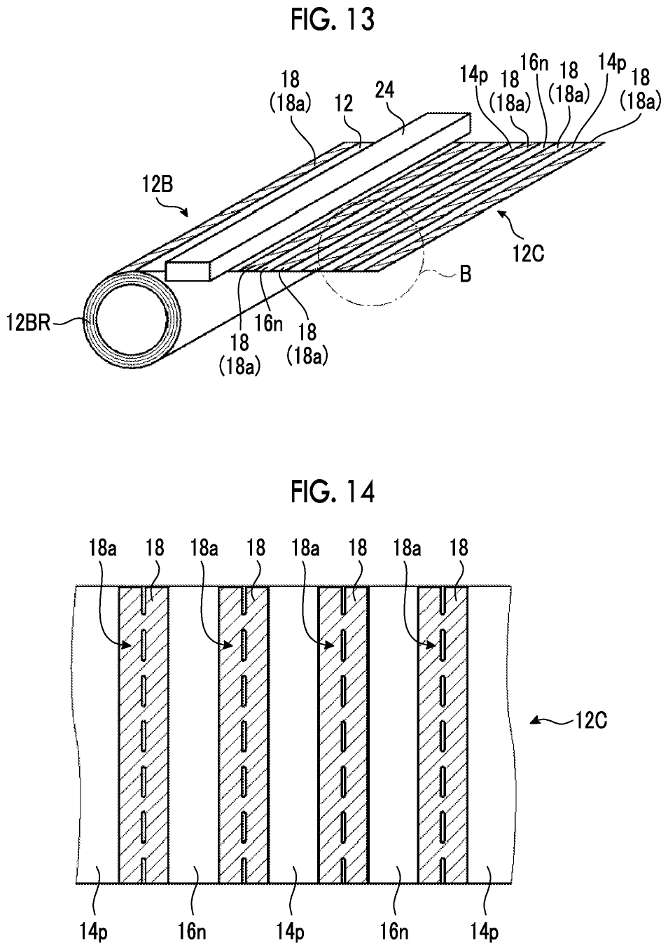

Next, as shown in FIG. 13, while the support 12B is pulled out from the support roll 12BR and transported in the longitudinal direction, the p-type thermoelectric conversion layer 14p and the n-type thermoelectric conversion layer 16n are alternately formed on the front surface of the support 12 exposed by etching using a film forming device 24. FIG. 14 shows a plan view showing the front surface of a region B in FIG. 13.

Although not shown in the drawing, a support 12C on which the p-type thermoelectric conversion layer 14p and the n-type thermoelectric conversion layer 16n are formed is wound in a roll shape to form a support roll 12CR.

The formation of the p-type thermoelectric conversion layer 14p and the n-type thermoelectric conversion layer 16n by the film forming device 24 may be performed by a printing method such as screen printing or metal mask printing as described above.

In addition, in the case where the p-type thermoelectric conversion layer 14p and the n-type thermoelectric conversion layer 16n are formed of an inorganic material, the thermoelectric conversion layers may be formed by a film forming method such as sputtering, vacuum deposition, and the like as described above.

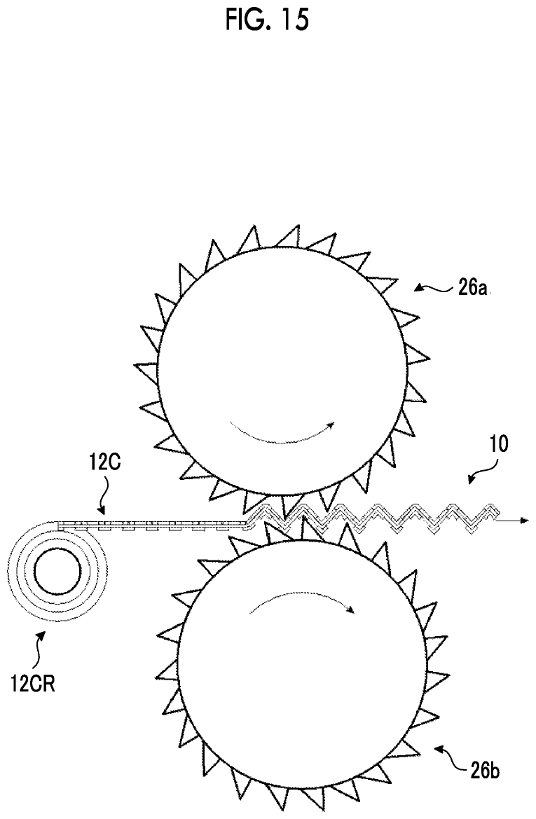

Further, as shown in FIG. 15, the module 10 according to the embodiment of the present invention is prepared by while pulling out the support 12C from the support roll 12CR and transporting the support in the longitudinal direction, bending the support 12C by passing through a space between gears 26a and 26b having a pitch narrower than the interval of the low rigidity portion in the longitudinal direction and engaged with each other.

As described above, the first low rigidity portions 18a and the second low rigidity portions 22a parallel to the width direction are formed on the support 12C at fixed intervals in the longitudinal direction. In addition, the gears 26a and 26b has a pitch narrower than the interval of the low rigidity portion. Accordingly, the support 12C is bent into a mountain fold or a valley fold at the low rigidity portion and the positions of all the top portions of the mountain fold portions and the bottom portions of the valley fold portions are aligned so that the bellows-like module 10 can be produced.

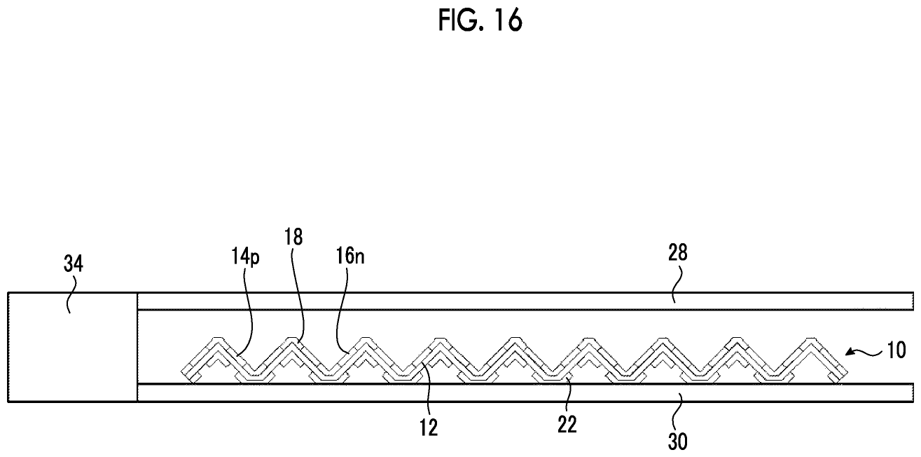

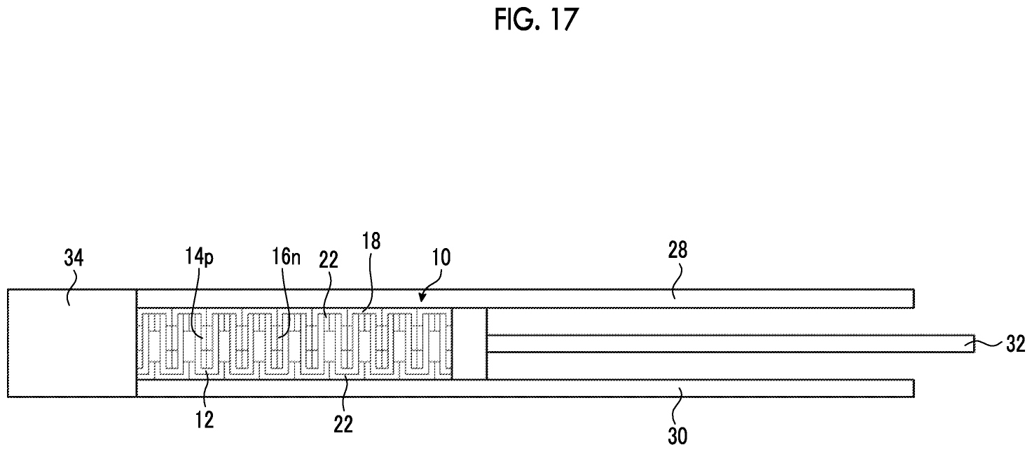

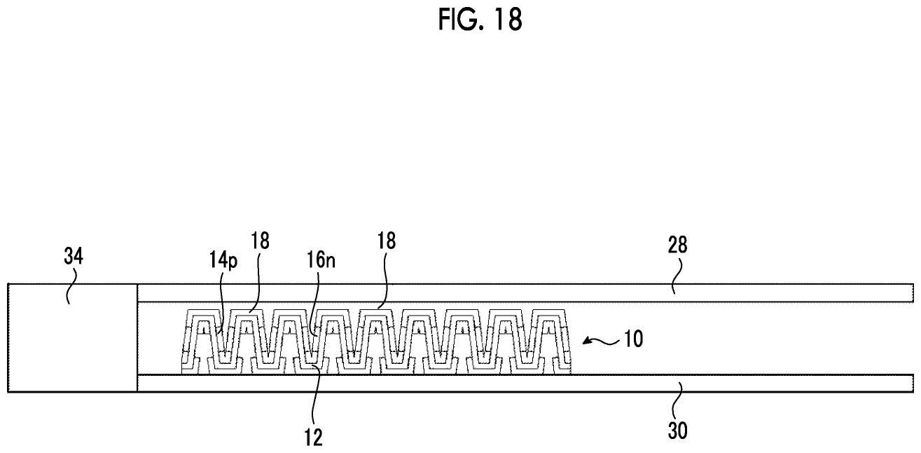

Further, if necessary, as shown in FIG. 18, the bent state of the module 10 may be controlled in such a manner that as shown in FIG. 16, the module 10 is inserted between an upper plate 28 and a lower plate 30 having an interval according to the interval of the low rigidity portion in the longitudinal direction and as shown in FIG. 17, the module is pressed against an abutting portion 34 by a pressing member 32 to compress the bent module 10 in the longitudinal direction.

As described above, the module 10 according to the embodiment of the present invention can be produced with high productivity using R to R.

In addition, since R to R can be used, for example, in a state in which an intermediate structure in the production of the module 10, such as the support 12B on which the connection electrode 18 and the second metal layer 22 are formed or the support 12C on which the p-type thermoelectric conversion layer 14p and the n-type thermoelectric conversion layer 16n are formed, is wound in a roll shape, the intermediate structure can be handled. Therefore, even in the case where the support 12 is a thin film having a thickness of 25 μm or less and preferably 15 μm or less, good handleability can be secured.

The method of producing the thermoelectric conversion module according to the embodiment of the present invention is not limited to the above example.

For example, in the above example, the connection electrode 18 and the second metal layer 22 are formed at the same time, but the present invention is not limited thereto. The connection electrode 18 and the second metal layer 22 may be formed separately, the connection electrode 18 may be formed first, or the second metal layer 22 may be formed first. For example, after the connection electrode 18 is formed, the p-type thermoelectric conversion layer 14p and the n-type thermoelectric conversion layer 16n are formed and then the second metal layer 22 may be formed.

The connection electrode 18 and the first low rigidity portion 18a are formed at the same time, but the present invention is not limited thereto. The connection electrode and the first low rigidity portion may be formed separately. For example, after the connection electrode 18 is formed, the p-type thermoelectric conversion layer 14p and the n-type thermoelectric conversion layer 16n may be formed and then the first low rigidity portion 18a may be formed.

In addition, the second metal layer 22 and the second low rigidity portion 22a are formed at the same time, but the present invention is not limited thereto. The second metal layer and the second low rigidity portion may be formed separately.

Alternatively, instead of using the laminate 12A with copper foil formed over the entire front surface and the entire rear surface of the support 12, a normal resin film may be used as the support 12, the p-type thermoelectric conversion layer 14p and the n-type thermoelectric conversion layer 16n may be formed on the front surface of the support 12 by printing or the like, then the connection electrode 18 may be formed by sputtering or vacuum deposition, and further the second metal layer 22 may be formed by sputtering or vacuum deposition. Then, the first low rigidity portion 18a may be formed in the connection electrode 18 and the second low rigidity portion 22a may be formed in the second metal layer.

In addition, for the bending processing, in addition to the method of using the gears engaged with each other, for example, a pressing method using a press plate having roughness narrower than the interval of the low rigidity portion in the longitudinal direction or the like can be used.

### EXAMPLES

Hereinafter, the present invention will be described in more detail based on examples. The material, the amount used, the ratio, the treatment and the treatment process shown in the following Examples may be appropriately changed as long as not departing from the spirit of the present invention. Accordingly, it should be construed that the scope of the present invention is not limited to the following examples.

### Example 1

<Preparation of Metal Layer>

A laminate having both surfaces formed of different metals in which a polyimide film having a thickness of 25 μm was used as a support, a copper foil having a thickness of 6 μm was bonded to the front surface of the support, and a SUS304 foil having a thickness of 50 μm was bonded to the rear surface (manufactured by UBE EXSYMO CO., LTD.) was prepared.

This laminate was cut to an outer diameter of 113 mm×65 mm by cutting.

Further, the laminate was etched, 11 rectangular portions of copper foil (longitudinal direction of support 5 mm×width direction 47 mm) were formed on the front surface side as connection electrodes at a 10 mm pitch in the longitudinal direction of the support and 11 rectangular portions of SUS foil (longitudinal direction 3 mm×width direction 47 mm of the support) were formed on the rear surface side at a 10 mm pitch in the longitudinal direction as second metal layers. At this time, the centers of the rectangular portions of the connection electrodes (copper foil) and the second metal layers (SUS foil) were arranged to be aligned, and slit portions of a size of width 0.12 mm×length 1 mm were formed at a 3 mm pitch at the center portions in the longitudinal direction to form low rigidity portions.

<Preparation of Thermoelectric Conversion Layer>

(Preparation of CNT Dispersion Liquid for p-Type Thermoelectric Conversion Layer)

15 ml of water was added to 112.5 mg of sodium deoxycholate (manufactured by Wako Pure Chemical Industries, Ltd.) and 37.5 mg of EC1.5 (manufactured by Meijo Nano Carbon Co., Ltd.) as a single layer CNT, and dispersed using a homogenizer HF93 (manufactured by SMT Co. Ltd.) at 18000 rpm for 5 minutes. Then, a dispersion treatment (circumferential speed: 40 m/s, stirring for 2.5 minutes) using high shearing force was performed twice using a FILMIX 40-40 model (manufactured by PRIMIX Corporation), thereby obtaining a CNT dispersion liquid for a p-type thermoelectric conversion layer.

The CNT dispersion liquid for a p-type thermoelectric conversion layer obtained as described above was printed on the polyimide substrate and evaluation was performed using a thermoelectric property measuring device MODEL RZ2001i (manufactured by OZAWA SCIENCE CO., LTD.). As a result, at a temperature of 100° C., a conductivity of 650 S/cm and a Seebeck coefficient of 50 μV/K were obtained.

(Preparation of CNT Dispersion Liquid for n-Type Thermoelectric Conversion Layer)

15 ml of water was added to 112.5 mg of sodium deoxycholate (manufactured by Wako Pure Chemical Industries, Ltd.), 37.5 mg of EMULGEN 350 (polyoxyethylene stearyl ether: manufactured by Kao Corporation), and 37.5 mg of EC1.5 (manufactured by Meijo Nano Carbon Co., Ltd.) as a single layer CNT and dispersed using a homogenizer HF93 (manufactured by SMT Co. Ltd.) at 18000 rpm for 5 minutes. Then, a dispersion treatment (circumferential speed: 40 m/s, stirring for 2.5 minutes) using high shearing force was performed twice using a FILMIX 40-40 model (manufactured by PRIMIX Corporation), thereby obtaining a CNT dispersion liquid for an n-type thermoelectric conversion layer.

The CNT dispersion liquid for an n-type thermoelectric conversion layer obtained as described above was printed on the polyimide substrate and evaluation was performed using a thermoelectric property measuring device MODEL RZ2001i (manufactured by OZAWA SCIENCE CO., LTD.). As a result, at a temperature of 100° C., a conductivity of 920 S/cm and a Seebeck coefficient of −46 μV/K were obtained.

(Formation of Thermoelectric Conversion Layer)

The CNT dispersion liquid for a p-type thermoelectric conversion layer was printed in 5 places in a size of 8 mm in the longitudinal direction of the support x 22 mm in the width direction among the rectangular portions of copper foil on the front surface side of the support every other rectangular portion.

Next, the CNT dispersion liquid for an n-type thermoelectric conversion layer was printed in 5 places in a size of 8 mm in the longitudinal direction of the support x 22 mm in the width direction among the rectangular portions of copper foil on the front surface side of the support on which the CNT dispersion liquid for a p-type thermoelectric conversion layer was not printed.

Further, after being immersed in ethanol for 30 minutes, the substrate was dried for 24 hours at room temperature to form a thermoelectric conversion layer. The thermoelectric conversion layer was formed so as to be in contact with adjacent connection electrodes in both end portions of the support in the longitudinal direction.

(Bending Processing)

The support on which the thermoelectric conversion layer was formed was processed in a bellows-like shape by alternately bending the support in a mountain fold or a valley fold at the position of the low rigidity portion.

Further, 5 bellows-like modules were connected in series using a silver paste FA-705BN (manufactured by FUJIKURA KASEI CO., LTD.) and the following evaluation was performed.

<Evaluation>

The initial performance (resistance and power generation capacity) of the prepared bellows-like module and performance (power generation capacity) after a cycle test were evaluated.

(Initial Performance: Resistance)

Voltage sweeping was performed at a 1 mV step in a range of 0 to 20 mV using a source meter 2450 (manufactured by Keithley Instruments, Inc.) and the resistance value was calculated from the slope of the obtained V-I properties.

(Initial Performance: Power Generation Capacity)

The bellows-like module was bonded and fixed to a pipe type heater of φ 80 mm using a heat conductive sheet TC-100TXS2 (manufactured by Shin-Etsu Chemical Co., Ltd.). The heater was heated to 120° C. and voltage sweeping was performed at a 1 mV step in a range of 0 to 20 mV using a source meter 2450. The resistance value from the slope of the obtained V-I properties and the open circuit voltage were calculated from the cut piece.

The power generation capacity was calculated from the following formula using the obtained resistance value and open circuit voltage.

(Power generation capacity)=0.25×(open circuit voltage)/(resistance)

(Cycle Test: Change Rate in Power Generation Capacity)

After the module was continuously driven on the pipe type heater at 120° C. for 3 hours, the heater was turned off and cooled to room temperature, and the module was continuously driven at 120° C. for 3 hours again. This operation was performed 10 times and the power generation capacity was obtained by the above-described measurement method to obtain the change rate from the initial power generation capacity.

### Example 2

A bellows-like module was prepared and evaluated in the same manner as in Example 1 except that the length of the rectangular portion of SUS304 foil as the second metal layer in the longitudinal direction of the support was 5 mm, that is, the length was the same as the length of the connection electrode.

### Example 3

A bellows-like module was prepared and evaluated in the same manner as in Example 1 except that the thickness of the second metal layer was changed to a 12.5 μm copper foil.

### Example 4

A bellows-like module was prepared and evaluated in the same manner as in Example 1 except that the thickness of the second metal layer was changed to a 6 μm copper foil.

### Example 5

A bellows-like module was prepared and evaluated in the same manner as in Example 2 except that the thickness of the second metal layer was changed to a 6 μm copper foil.

### Example 6

A bellows-like module was prepared and evaluated in the same manner as in Example 5 except that an auxiliary electrode was formed at the connection position of the thermoelectric conversion layer and the connection electrode.

Printing was performed using a silver paste FA-333 (manufactured by FUJIKURA KASEI CO., LTD.) for the material of the auxiliary electrode by a screen printing method such that the silver paste covered 1 mm of the thermoelectric conversion layer and 1 mm of each connection electrode at the connection positions of the thermoelectric conversion layer and the connection electrodes in both end portions of the support in the longitudinal direction and the length in the width direction of the support matched the length of the thermoelectric conversion layer. After the printing, the silver paste was dried on a hot plate at 120° C. for 10 minutes to form auxiliary electrodes.

### Example 7

A bellows-like module was prepared and evaluated in the same manner as in Example 6 except that the auxiliary electrodes were formed such that the length in the width direction of the support was 1 mm longer than the length of the thermoelectric conversion layer.

### Example 8

A bellows-like module was prepared and evaluated in the same manner as in Example 7 except that the auxiliary electrodes having a substantially C shape were formed in both end portions in the width direction of the support at the connection positions of the thermoelectric conversion layer and the connection electrodes were in a size of 2 mm in the longitudinal direction of the support x 1 mm in the width direction so to cover the thermoelectric conversion layer and the support.

At this time, the overlapping width of the thermoelectric conversion layer and the auxiliary electrode in the width direction of the support was 0.5 mm.

### Comparative Example 1

A bellows-like module was prepared and evaluated in the same manner as in Example 5 except that the second metal layer was not provided.

### Comparative Example 2

A bellows-like module was prepared and evaluated in the same manner as in Example 5 except that the second metal layer was formed only at the position of the bottom portion (valley portion) in the case of bending the module in a bellows-like shape and was not formed at the position of the top portion (mountain portion).

### Example 9

A bellows-like module was prepared and evaluated in the same manner as in Example 7 except that the thermoelectric conversion layer was formed as described below.

(Preparation of CNT Buckypaper)

To 800 mg of EC1.5 (manufactured by Meijo Nano Carbon Co., Ltd.) as a single layer CNT, 400 ml of acetone (manufactured by Wako Pure Chemical Industries, Ltd.) was added, and dispersed using homogenizer HF93 (manufactured by SMT Co. Ltd.) at 18000 rpm for 5 minutes to obtain a CNT dispersion liquid. Next, the dispersion liquid was filtered using qualitative filter paper No. 2 of φ 125 mm (manufactured by Toyo Roshi Kaisha, Ltd.) and then the resultant was dried on a hot plate at 50° C. for 30 minutes and then at 120° C. for 30 minutes to prepare a CNT buckypaper.

(Preparation of p-Type CNT Buckypaper)

One buckypaper prepared above was immersed in a liquid obtained by dissolving 670 mg of pyridine hydrochloride (manufactured by Tokyo Chemical Industry Co., Ltd.) in 620 ml of methanol (manufactured by Wako Pure Chemical Industries, Ltd.) for 2 hours. Next, using a vacuum specimen dryer HD-200 (manufactured by Ishii Laboratory Works Co., Ltd.) whose temperature was set to 30° C., the buckypaper after immersion was vacuum dried for 4 hours under the condition of a gage pressure of −0.1 MPa.

Next, the buckypaper was pressed under the conditions of a roll rotation speed of 1.0 m/min and a load of 20 kN using a roll press SA-602 (manufactured by Tester Sangyo Co., Ltd.) to obtain a p-type CNT buckypaper having a thickness of 33 μm. In the p-type CNT buckypaper, pyridine hydrochloride is a dopant.

This p-type CNT buckypaper was evaluated using a thermoelectric property measuring device MODEL RZ2001i (manufactured by OZAWA SCIENCE CO., LTD.) and thus at a temperature of 100° C., a conductivity of 1700 S/cm and a Seebeck coefficient of 65 μV/K were obtained.

(Preparation of n-Type CNT Buckypaper)

One buckypaper prepared above was immersed in a liquid obtained by dissolving 2.17 g of methyltri-n-octylammonium chloride (manufactured by Tokyo Chemical Industry Co., Ltd.) in 520 ml of methanol (manufactured by Wako Pure Chemical Industries, Ltd.) for 2 hours. Next, using a vacuum specimen dryer HD-200 (manufactured by Ishii Laboratory Works Co., Ltd.) whose temperature was set to 30° C., the buckypaper after immersion was vacuum dried for 4 hours under the condition of a gage pressure of −0.1 MPa.

Next, the buckypaper was pressed under the conditions of a roll rotation speed of 1.0 m/min and a load of 20 kN using a roll press SA-602 (manufactured by Tester Sangyo Co., Ltd.) to obtain an n-type CNT buckypaper having a thickness of 34 μm. In the n-type CNT buckypaper, methyltri-n-octylammonium chloride is a dopant.

This n-type CNT buckypaper was evaluated using a thermoelectric property measuring device MODEL RZ2001i (manufactured by OZAWA SCIENCE CO., LTD.) and thus at a temperature of 100° C., a conductivity of 2100 S/cm and a Seebeck coefficient of −61 μV/K were obtained.

(Formation of Thermoelectric Conversion Layer)

The p-type CNT buckypaper and the n-type CNT buckypaper prepared above were respectively cut into a size of 8 mm×22 mm to form a p-type thermoelectric conversion element and an n-type thermoelectric conversion element.

Next, a silver paste FA-333 (all manufactured by FUJIKURA KASEI CO., LTD.) was printed in plurality of places on which the thermoelectric conversion elements are mounted on the copper foil (connection electrode) of the support prepared in the same manner as in Example 5 respectively in a size of 2 mm in the longitudinal direction of the support x 22 mm in the width direction. At predetermined positions of the copper foil with the printed silver paste, the n-type CNT thermoelectric conversion element and the p-type CNT thermoelectric conversion element were bonded and then dried on a hot plate at 120° C. for 10 minutes.

(Formation of Auxiliary Electrode)

An auxiliary electrodes was formed at the connection position of the thermoelectric conversion layer and the connection electrode in the same manner as in Example 7.

### Example 10

A bellows-like module was prepared and evaluated in the same manner as in Example 7 except that the thermoelectric conversion layer was formed as described below.

(Preparation of p-Type CNT Buckypaper)

To 200 mg of EC1.5 (manufactured by Meijo Nano Carbon Co., Ltd.) as a single layer CNT, 400 ml of acetone (manufactured by Wako Pure Chemical Industries, Ltd.) was added and dispersed using a homogenizer HF93 (manufactured by SMT Co. Ltd.) at 18000 rpm for 5 minutes to obtain a CNT dispersion liquid. Next, the dispersion liquid was filtered using qualitative filter paper No. 2 of φ 125 mm (manufactured by Toyo Roshi Kaisha, Ltd.) and then the resultant was dried on a hot plate at 50° C. for 30 minutes and then at 120° C. for 30 minutes to prepare a CNT buckypaper.

(Preparation of p-Type CNT Buckypaper)

One buckypaper prepared above was immersed in a liquid obtained by dissolving 170 mg of pyridine hydrochloride (manufactured by Tokyo Chemical Industry Co., Ltd.) in 620 ml of methanol (manufactured by Wako Pure Chemical Industries, Ltd.) for 2 hours. Next, using a vacuum specimen dryer HD-200 (manufactured by Ishii Laboratory Works Co., Ltd.) whose temperature was set to 30° C., the buckypaper after immersion was vacuum dried for 4 hours under the condition of a gage pressure of −0.1 MPa.

Next, the buckypaper was pressed under the conditions of a roll rotation speed of 1.0 m/min and a load of 20 kN using a roll press SA-602 (manufactured by Tester Sangyo Co., Ltd.) to obtain a p-type CNT buckypaper having a thickness of 5.2 μm.

This p-type CNT buckypaper was evaluated using a thermoelectric property measuring device MODEL RZ2001i (manufactured by OZAWA SCIENCE CO., LTD.) and thus at a temperature of 100° C., a conductivity of 3800 S/cm and a Seebeck coefficient of 68 μV/K were obtained.

(Preparation of n-Type CNT Buckypaper)

One buckypaper prepared above was immersed in a liquid obtained by dissolving 543 mg of methyltri-n-octylammonium chloride (manufactured by Tokyo Chemical Industry Co., Ltd.) in 520 ml of methanol (manufactured by Wako Pure Chemical Industries, Ltd.) for 2 hours. Next, using a vacuum specimen dryer HD-200 (manufactured by Ishii Laboratory Works Co., Ltd.) whose temperature was set to 30° C., the buckypaper after immersion was vacuum dried for 4 hours under the condition of a gage pressure of −0.1 MPa.

Next, the buckypaper was pressed under the conditions of a roll rotation speed of 1.0 m/min and a load of 20 kN using a roll press SA-602 (manufactured by Tester Sangyo Co., Ltd.) to obtain an n-type CNT buckypaper having a thickness of 9.1 μm.

This n-type CNT buckypaper was evaluated using a thermoelectric property measuring device MODEL RZ2001i (manufactured by OZAWA SCIENCE CO., LTD.) and thus at a temperature of 100° C., a conductivity of 3290 S/cm and a Seebeck coefficient of −57 μV/K were obtained.

(Formation of Thermoelectric Conversion Layer)

The p-type CNT buckypaper and the n-type CNT buckypaper prepared above were respectively cut into a size of 8 mm×22 mm to form a p-type thermoelectric conversion element and an n-type thermoelectric conversion element.

Next, a silver paste FA-333 (all manufactured by FUJIKURA KASEI CO., LTD.) was printed in plurality of places on which the thermoelectric conversion elements are mounted on the copper foil (connection electrode) of the support prepared in the same manner as in Example 5 respectively in a size of 2 mm in the longitudinal direction of the support x 22 mm in the width direction. At predetermined positions of the copper foil with the printed silver paste, the n-type CNT thermoelectric conversion element and the p-type CNT thermoelectric conversion element were bonded and then dried on a hot plate at 120° C. for 10 minutes.

(Formation of Auxiliary Electrode)

An auxiliary electrode was formed at the connection position of the thermoelectric conversion layer and the connection electrode in the same manner as in Example 7.

The results are shown in Table 1.

TABLE 1

| | | | | | | | | Evaluation | | |
|---|---|---|---|---|---|---|---|---|---|---|
| | | | | | | | | | | After |
| | | | | | | | | | | cycle test |
| | Connection electrode | | | Second metal layer | | | | Initial performance | | Change rate |
| | | | Length in | | | Length in | | | Power | of power |
| | | | longitudinal | | | longitudinal | | | generation | generation |
| | | Thickness | direction | | Thickness | direction | Auxiliary | Resistance | capacity | capacity |
| | Material | μm | mm | Material | μm | mm | electrode | Ω | μW | % |
| Example 1 | Copper | 6 | 5 | SUS | 50 | 3 | None | 25.2 | 7.33 | −7.8 |
| Example 2 | Copper | 6 | 5 | SUS | 50 | 5 | None | 25.2 | 7.21 | −7 |
| Example 3 | Copper | 6 | 5 | Copper | 12.5 | 3 | None | 25.2 | 6.24 | −6.3 |
| Example 4 | Copper | 6 | 5 | Copper | 6 | 3 | None | 25.2 | 5.98 | −5.2 |
| Example 5 | Copper | 6 | 5 | Copper | 6 | 5 | None | 25.2 | 5.85 | −4.7 |
| Example 6 | Copper | 6 | 5 | Copper | 6 | 5 | 2 × 22 mm | 17.8 | 8.28 | −3.2 |
| Example 7 | Copper | 6 | 5 | Copper | 6 | 5 | 2 × 23 mm | 14.1 | 10.5 | −2.9 |
| Example 8 | Copper | 6 | 5 | Copper | 6 | 5 | Substantially | 13.4 | 11 | −1.4 |
| | | | | | | | C shape | | | |
| Comparative | Copper | 6 | 5 | — | — | — | None | 25.2 | 3.63 | −12.6 |
| Example 1 | | | | | | | | | | |
| Comparative | Copper | 6 | 5 | Copper | 6 | 5 | None | 25.2 | 5.85 | −10.9 |
| Example 2 | | | | (Only | | | | | | |
| | | | | bottom | | | | | | |
| | | | | portion) | | | | | | |
| Example 9 | Copper | 6 | 5 | Copper | 6 | 5 | 2 × 23 mm | 3.4 | 13.5 | −1.3 |
| Example 10 | Copper | 6 | 5 | Copper | 6 | 5 | 2 × 23 mm | 10 | 14 | −1.8 |

From Table 1, it is found that in Examples, compared to Comparative Examples, the initial power generation capacity is higher and the change rate of the power generation capacity after a cycle test is low. It is considered that the module of the present invention can be reliably brought into contact with the heat source since the bellows-like shape of the module can be maintained, and the contact of the module with the heat source can be maintained since the bent shape is not changed over time and due to application of heat.

From the comparison with Examples 1 to 5, it is found that it is preferable that the second metal layer is formed of the same kind of metal as the connection electrode and has the same shape and size.

From the comparison with Examples 5 to 8, it is found that it is preferable to provide the auxiliary electrode at the connection position of the thermoelectric conversion layer and the connection electrode.

From Examples 7, 9, and 10, it is found that higher effects can be obtained by using buckypaper as the thermoelectric conversion layer.

From the above result, the effects of the present invention are apparent.

While the thermoelectric conversion module of the present invention has been described above, the present invention is not limited to the above-described examples and various improvements and modifications may of course be made without departing from the spirit of the present invention.

The present invention can be suitably used for a power generation device and the like.

### EXPLANATION OF REFERENCES

10: (thermoelectric conversion) module
12, 12B, 12C: support
12A: laminate
12AR: roll
12BR, 12CR: support roll
12M: metal film
14p: p-type thermoelectric conversion layer
16n: n-type thermoelectric conversion layer
18: connection electrode
18a: first low rigidity portion
19: auxiliary electrode
20A, 20B: etching device
22, 22B: second metal layer
22a: second low rigidity portion
23: reinforcing member
23a: through-hole
24: film forming device
26a, 26b: gear
28: upper plate
30: lower plate
32: pressing member
34: abutting portion
70: wire

What is claimed is:

1. A thermoelectric conversion module comprising:
a long support having flexibility and insulating properties;
a plurality of first metal layers formed on one surface of the support at intervals in a longitudinal direction of the support;
a plurality of thermoelectric conversion layers formed on the same surface of the support as the surface provided with the first metal layers at intervals in the longitudinal direction of the support;
a connection electrode for connecting the thermoelectric conversion layers adjacent in the longitudinal direction of the support on the same surface of the support as the surface provided with the first metal layers; and
a second metal layer formed on a surface of the support opposite to the surface on which the first metal layer is formed,
wherein the first metal layer has a first low rigidity portion having rigidity lower than rigidity of other regions and extending in a width direction of the support,
the second metal layer has a second low rigidity portion having rigidity lower than rigidity of other regions and extending in the width direction of the support,
the second low rigidity portions of the second metal layer are formed at the same positions as each first low rigidity portion of the plurality of first metal layers in the longitudinal direction of the support, and
the support is alternately bent into a mountain fold and a valley fold at the first low rigidity portions of the plurality of first metal layers and the second low rigidity portions of the second metal layer in the longitudinal direction.

2. The thermoelectric conversion module according to claim 1,
wherein the connection electrode also functions as the first metal layer.

3. The thermoelectric conversion module according to claim 1,
wherein the plurality of first low rigidity portions are formed at fixed intervals in the longitudinal direction of the support.

4. The thermoelectric conversion module according to claim 1,
wherein a material forming the first metal layer is the same as a material forming the second metal layer.

5. The thermoelectric conversion module according to claim 1,
wherein a thickness of the first metal layer is the same as a thickness of the second metal layer.

6. The thermoelectric conversion module according to claim 1,
wherein a plurality of the second metal layers are formed at intervals in the longitudinal direction of the support.

7. The thermoelectric conversion module according to claim 1,
wherein the plurality of first metal layers having a fixed length are formed at intervals in a longitudinal direction of the support, and
a plurality of the second metal layers having a fixed length are formed at intervals in the longitudinal direction of the support.

8. The thermoelectric conversion module according to claim 1,
wherein a shape and a size of the second metal layer are the same as a shape and a size of the first metal layer.

9. The thermoelectric conversion module according to claim 1,
wherein the plurality of first metal layers are bonded to the support, and
the second metal layer is bonded to the support.

10. The thermoelectric conversion module according to claim 1, further comprising:
an auxiliary electrode in contact with the thermoelectric conversion layer and the connection electrode.

11. The thermoelectric conversion module according to claim 10,
wherein a part of the auxiliary electrode covers a part of the support.

12. The thermoelectric conversion module according to claim 1,
wherein the first low rigidity portion and the second low rigidity portion are at least one of one or more slits parallel to the width direction of the support or broken line portions parallel to the width direction of the support.

13. The thermoelectric conversion module according to claim 1,
wherein the plurality of thermoelectric conversion layers include a p-type thermoelectric conversion layer and an n-type thermoelectric conversion layer that are alternately formed in the longitudinal direction of the support.
